(19) United States
(12) Patent Application Publication
(10) Pub. No.: US 2022/0278039 A1
(43) Pub. Date: Sep. 1, 2022

(54) SEMICONDUCTOR MODULE AND METHOD FOR MANUFACTURING SEMICONDUCTOR MODULE

(71) Applicant: FUJI ELECTRIC CO., LTD., Kanagawa (JP)

(72) Inventors: Mai SAITO, Matsumoto-city (JP); Akihiko IWAYA, Suginami-ku (JP); Yoko NAKAMURA, Matsumoto-city (JP); Tatsuhiko ASAI, Kawasaki-city (JP); Hiromichi GOHARA, Matsumoto-city (JP); Tsubasa WATAKABE, Matsumoto-city (JP); Narumi SATO, Matsumoto-city (JP)

(21) Appl. No.: 17/746,889

(22) Filed: May 17, 2022

Related U.S. Application Data
(63) Continuation of application No. PCT/JP2021/024649, filed on Jun. 29, 2021.

(30) Foreign Application Priority Data
Jun. 30, 2020 (JP) 2020-113562
Oct. 30, 2020 (JP) 2020-183102
Mar. 11, 2021 (JP) 2021-039453

(51) Int. Cl. H01L 23/498; H01L 23/00; H01L 21/48

(52) U.S. Cl. CPC H01L 23/49861; H01L 24/32; H01L 24/33; H01L 23/49844; H01L 21/4839; H01L 2224/32225; H01L 2224/32245; H01L 2224/3303; H01L 2224/33181; H01L 2924/35121; H01L 2924/1811; H01L 2924/1815; H01L 2924/182; H01L 2924/186; H01L 23/49822

(57) ABSTRACT

Provided is a semiconductor module including: an insulating circuit board having a circuit pattern formed in one surface; a semiconductor chip placed in the insulating circuit board; and a wiring portion for electrically connecting the semiconductor chip and the circuit pattern. The wiring portion includes a chip connecting portion connected to the semiconductor chip. A surface of the chip connecting portion includes: a plurality of concave portions; and a flat portion disposed between two concave portions.

The contents of the following Japanese patent applications are incorporated herein by reference:

NO. 2020-113562 filed in JP on Jun. 30, 2020,

NO. 2020-183102 filed in JP on Oct. 30, 2020,

NO. 2021-039453 filed in JP on Mar. 11, 2021, and

PCT/JP2021/024649 filed in WO on Jun. 29, 2021.

### BACKGROUND

### 1. Technical Field

The present invention relates to a semiconductor module and a method for manufacturing the semiconductor module.

### 2. Related Art

Conventionally, there has been known a semiconductor module in which a semiconductor chip is mounted on an insulating circuit board, and the semiconductor chip and a circuit pattern of the insulating circuit board are connected at a wiring portion such as a lead frame. In such a semiconductor module, various resin packages are used to protect the semiconductor chip (see, for example, Patent Document 1).

Patent Document 1: WO 2017/163583

### BRIEF DESCRIPTION OF THE DRAWINGS

FIG. 1 is a diagram illustrating an example of a semiconductor module 100 according to one embodiment of the present invention.

FIG. 2 is a diagram illustrating an example of an insulating circuit board 160.

FIG. 3 is a sectional view taken along line A-A of FIG. 2.

FIG. 4 is an enlarged view of a lead frame 50 of FIG. 3.

FIG. 5 is an enlarged view of the vicinity of a circuit pattern connecting portion 56.

FIG. 6 is an enlarged view of the vicinity of an edge surface 66 of FIG. 3.

FIG. 7 is a diagram illustrating the relationship between a developed interfacial area ratio and an adhesion strength in the lead frame 50.

FIG. 8 is a perspective view illustrating another structural example of the lead frame 50.

FIG. 9 is a diagram illustrating a lower surface 62 of a chip connecting portion 52 of FIG. 8.

FIG. 10 is a diagram illustrating a cross section B-B in FIG. 9.

FIG. 11 is a diagram illustrating a cross section C-C in FIG. 9.

FIG. 12 is an enlarged view of the vicinity of the edge surface 66 when the lead frame 50 of FIG. 8 is applied.

FIG. 13 is a diagram illustrating another example of the lower surface 62 of the chip connecting portion 52.

FIG. 14 is a diagram illustrating a cross section D-D in FIG. 13.

FIG. 15 is a diagram illustrating a cross section E-E in FIG. 13.

FIG. 16 is a diagram illustrating another example of the lower surface 62 of the chip connecting portion 52.

FIG. 17 is a diagram illustrating a cross section F-F in FIG. 16.

FIG. 18 is a diagram illustrating a cross section G-G in FIG. 16.

FIG. 19 is a diagram illustrating another example of the lower surface 62 of the chip connecting portion 52.

FIG. 20 is a diagram illustrating a cross section H-H in FIG. 19.

FIG. 21 is a diagram illustrating a cross section I-I in FIG. 19.

FIG. 22 is a diagram illustrating a chip connecting portion 152 according to a reference example.

FIG. 23 is an enlarged view of the vicinity of a vertex 201 of the chip connecting portion 152.

FIG. 24 is a diagram illustrating another example of the lead frame 50.

FIG. 25 is an enlarged view of the vicinity of the edge surface 66 of the chip connecting portion 52.

FIG. 26 is a diagram illustrating an example of a concave portion 210 and a flat portion 212 in the edge surface 66.

FIG. 27 is a diagram illustrating an arrangement example of the concave portion 210 and the flat portion 212 in the edge surface 66.

FIG. 28 is a diagram illustrating another arrangement example of the concave portion 210 and the flat portion 212 in the edge surface 66.

FIG. 29 is a diagram illustrating some steps in the method of manufacturing the semiconductor module 100.

FIG. 30 is a diagram illustrating measurement results of first to third examples and first to third reference examples.

FIG. 31 is a diagram for explaining laser irradiation to the chip connecting portion 52.

FIG. 32 is a diagram illustrating an example of laser irradiation in Step S341 of FIG. 29.

FIG. 33 is a diagram illustrating another example of laser irradiation in Step S341 of FIG. 29.

FIG. 34 is a diagram illustrating another example of laser irradiation in Step S341 of FIG. 29.

FIG. 35 is a diagram illustrating another example of laser irradiation in Step S341 of FIG. 29.

FIG. 36 is a diagram illustrating an example of the surface shapes of the concave portions 210 of the edge surface 66 and the upper surface 64.

FIG. 37 is a diagram for explaining the shapes of the concave portions 210 in the edge surface 66 and the upper surface 64.

FIG. 38 is a diagram illustrating an example of the arrangement of the concave portions 210 of the upper surface 64 and the edge surface 66.

FIG. 39 is a diagram illustrating an example of the arrangement of the concave portions 210 of the upper surface 64 and the edge surface 66.

FIG. 40 is a diagram illustrating an example of the arrangement of the concave portions 210 of the upper surface 64 and the edge surface 66.

FIG. 41 is a diagram illustrating an example of the arrangement of the concave portions 210 of the upper surface 64 and the edge surface 66.

FIG. 42 is a diagram illustrating another arrangement example of the concave portions 210 and the flat portion 212 in the edge surface 66.

FIG. 43 is a diagram illustrating another arrangement example of the concave portions 210 and the flat portion 212 in the edge surface 66.

FIG. 44 is a diagram illustrating another arrangement example of the concave portions 210 and the flat portion 212 in the edge surface 66.

FIG. 45 is a diagram illustrating another arrangement example of the concave portions 210 and the flat portion 212 in the edge surface 66.

FIG. 46 is a diagram illustrating some steps in the method of manufacturing the semiconductor module 100.

FIG. 47 is a diagram for explaining shape transfer to the chip connecting portion 52 by a die 320.

FIG. 48 is a diagram illustrating an example of the arrangement of the concave portions 210 and the flat portion 212 of the upper surface 64.

FIG. 49 is a diagram for explaining the shapes of the concave portions 210 and the flat portion 212 of the upper surface 64 in detail.

FIG. 50 is a diagram illustrating some steps in the method of manufacturing the semiconductor module 100.

FIG. 51 is a diagram for explaining the shape of the chip connecting portion 52.

FIG. 52 is a diagram illustrating an example of the arrangement of the concave portions 210 and the flat portions 212 of the upper surface 64 and the edge surface 66.

FIG. 53 is a diagram illustrating an example of the arrangement of the concave portions 210 of the upper surface 64, the edge surface 66, and the lower surface 62.

FIG. 54 is a diagram illustrating another example of the arrangement of an inhibition region 251.

FIG. 55 is a diagram illustrating an example of the arrangement of the concave portions 210 of the upper surface 64 and the edge surface 66 in FIG. 54.

FIG. 56 is a diagram illustrating an example of a chip connecting portion 52 according to a comparative example.

FIG. 57 is a diagram illustrating another example of the arrangement of the inhibition region 251.

FIG. 58 is a diagram illustrating another example of the arrangement of the inhibition region 251.

FIG. 59 is a diagram illustrating an example of the arrangement of the concave portions 210 of the upper surface 64 and the edge surface 66 in FIG. 58.

FIG. 60 is a diagram for explaining laser irradiation to the chip connecting portion 52 according to the comparative example.

FIG. 61 is a diagram illustrating another example of the arrangement of the inhibition region 251.

FIG. 62 is a diagram illustrating another example of the arrangement of the inhibition region 251.

FIG. 63 is a diagram illustrating another example of the arrangement of the inhibition region 251.

FIG. 64 is a diagram illustrating an example of the arrangement of the concave portions 210 of the upper surface 64 and the edge surface 66 in FIG. 63.

FIG. 65 is a diagram for explaining the shape of an overlapping portion 332.

FIG. 66 is a diagram illustrating another example of the lead frame 50.

FIG. 67 is a diagram illustrating an arrangement example of a main material portion 231 and an inhibition portion 230 in the chip connecting portion 52.

FIG. 68 is a diagram illustrating another example of the lead frame 50.

FIG. 69 is an enlarged schematic view of the chip connecting portion 52 in FIG. 37.

FIG. 70 is a diagram illustrating another example of the lead frame 50.

FIG. 71 is a diagram illustrating an arrangement example of the inhibition portions 230 in the lower surface 62 of the chip connecting portion 52.

FIG. 72 is an enlarged schematic view of the chip connecting portion 52 in FIG. 70 and FIG. 71.

FIG. 73 is a diagram illustrating another arrangement example of the inhibition portion 230 in the lower surface 62 of the chip connecting portion 52.

FIG. 74 is a diagram illustrating another arrangement example of the main material portion 231 and the inhibition portion 230 in the chip connecting portion 52.

FIG. 75 is a diagram illustrating another arrangement example of the main material portion 231 and the inhibition portion 230 in the chip connecting portion 52.

FIG. 76 is a diagram illustrating another arrangement example of the main material portion 231 and the inhibition portion 230 in the chip connecting portion 52.

### DESCRIPTION OF EXEMPLARY EMBODIMENTS

Hereinafter, the present invention will be described through embodiments of the invention, but the following embodiments do not limit the invention according to the claims. Not all combinations of features described in the embodiments are essential to the solution of the invention. Note that, in the present specification and the drawings, elements having substantially the same function and configuration are denoted by the same reference numerals, and redundant description is omitted, and elements not directly related to the present invention are not illustrated. In one drawing, elements having the same function and configuration are representatively denoted by a reference numeral, and the reference numerals for the others may be omitted.

As used herein, one side in a direction parallel to a depth direction of a semiconductor chip is referred to as “upper” and the other side is referred to as “lower”. One of two main surfaces of a substrate, a layer or other member is referred to as an upper surface, and the other surface is referred to as a lower surface. “Upper” and “lower” directions are not limited to a direction of gravity, or a direction in which a semiconductor module is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. The Z axis direction described without positive or negative sign means a direction parallel to the +Z axis and the −Z axis. In the present specification, orthogonal axes parallel to the upper surface and the lower surface of the semiconductor chip are referred to as the X axis and the Y axis. An axis perpendicular to the upper surface and the lower surface of the semiconductor substrate is referred to as the Z axis. In the present specification, the direction of the Z axis may be referred to as the depth direction. In the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error caused by a variation in manufacturing or the like is included. The error is, for example, within 10%.

### Present Embodiment

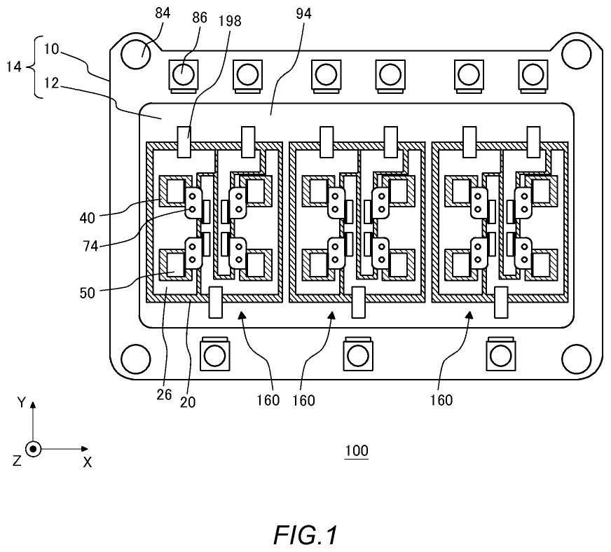

FIG. 1 is a diagram illustrating an example of a semiconductor module 100 according to one embodiment of the present invention. The semiconductor module 100 may function as a power conversion apparatus such as an inverter. The semiconductor module 100 includes one or more insulating circuit boards 160. In the present specification, orthogonal axes on a surface on which the one or more insulating circuit boards 160 are provided are referred to as an X axis and a Y axis, and an axis perpendicular to the XY plane is referred to as a Z axis. FIG. 1 illustrates an arrangement example of each member in the XY plane.

Description of Semiconductor Module 100

The semiconductor module 100 of the present example includes three insulating circuit boards 160 constituting arms of a U layer, a V layer, and a W layer respectively. One or more semiconductor chips 40 are placed in the insulating circuit board 160. The semiconductor chip 40 is protected by a resin package 14 such as a resin case 10 surrounding the insulating circuit board 160 and a resin 12 filled in the resin case 10.

The semiconductor chip 40 may include a diode such as an insulated gate bipolar transistor (IGBT) or a free wheel diode (FWD), a reverse conducting (RC)-IGBT obtained by combining these diodes, a MOS transistor, and the like.

The resin case 10 is provided so as to surround the space 94 accommodating the insulating circuit board 160. One or more terminals 86 may be provided to be exposed from the resin case 10. The terminal 86 may be electrically connected to the insulating circuit board 160 via a terminal connecting portion 198. The resin case 10 may be provided with a through hole 84 into which a fastening member such as a screw for fixing a cooling apparatus or the like is inserted.

In the present example, the resin case 10 is made of a resin such as a thermosetting resin that can be formed by injection molding or an ultraviolet curable resin that can be formed by UV molding. The resin may contain one or a plurality of polymer materials selected from, for example, a polyphenylene sulfide (PPS) resin, a polybutylene terephthalate (PBT) resin, a polyamide (PA) resin, an acrylonitrile butadiene styrene (ABS) resin, an acrylic resin, and the like.

In the present example, the resin 12 is provided in an inner portion of the resin case 10. The resin 12 is, for example, an epoxy resin or silicone gel, but not limited to this. The insulating circuit board 160 can be protected by the resin 12.

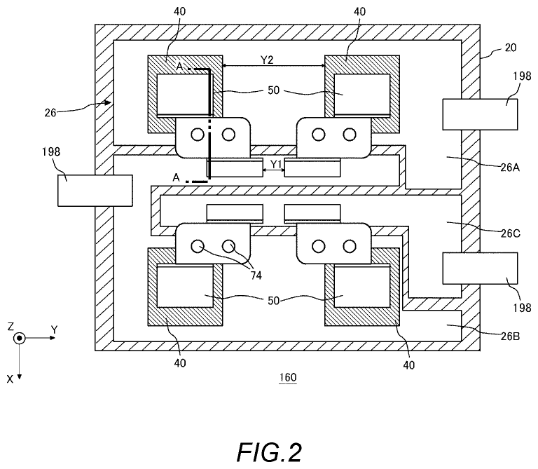

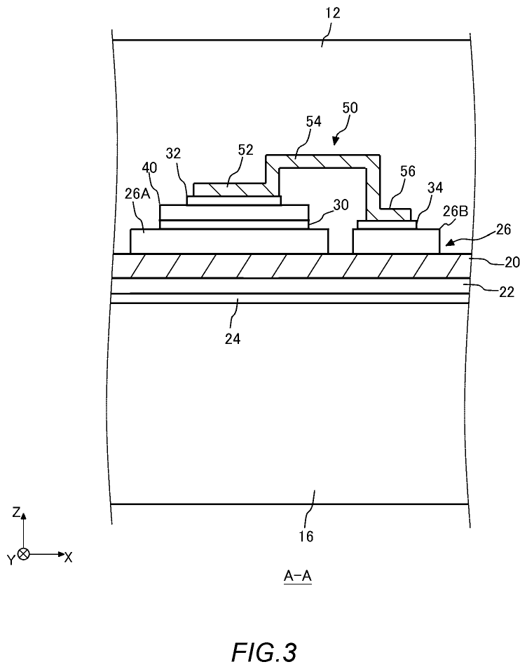

FIG. 2 is a diagram illustrating an example of the insulating circuit board 160. Here, the insulating circuit board 160 constituting one phase arm as a representative is exemplified, but the insulating circuit boards 160 of the other phases also have the similar configuration. The insulating circuit board 160 of the present example is provided with a circuit pattern 26 in any one surface of an insulating board 20, and provided with a heat dissipation plate 22 (see FIG. 3) on the other surface. The circuit pattern 26 and the heat dissipation plate 22 may be configured by directly bonding a copper plate, an aluminum plate, or a plate obtained by plating these materials to the insulating board 20 such as silicon nitride ceramics or aluminum nitride ceramics, or by bonding these plates via a brazing material layer interposed therebetween.

The semiconductor chip 40 of the present example is bonded to the circuit pattern 26 provided in the upper surface of the insulating board 20 via a bonding layer 30 (see FIG. 3) such as solder. The upper surface of the semiconductor chip 40 is connected to a wiring portion via a bonding layer 32 (see FIG. 3) made of solder or the like. The wiring portion of the present example is a lead frame 50. The lead frame 50 connects the semiconductor chip 40 to the circuit pattern 26 via a bonding layer 34 (see FIG. 3) made of solder or the like. The lead frame 50 is a member formed of a metal material such as copper or aluminum. At least a part of the surface of the lead frame 50 may be plated with nickel or the like. At least a part of the surface of the lead frame 50 may be coated with resin or the like. The lead frame 50 may have a plate-shaped portion. The plate shape refers to a shape in which the areas of two main surfaces disposed opposite to each other are larger than the areas of the other surfaces. At least a portion of the lead frame 50 connected to the semiconductor chip 40 may have a plate shape. The lead frame 50 may be formed by bending one metal plate.

The circuit pattern 26 is electrically connected to the semiconductor chip 40 or the lead frame 50 to transmit a signal or power. The circuit pattern 26 may be configured to include a plurality of island-shaped regions 26A, 26B, and 26C. A plurality of semiconductor chips 40 may be disposed in one island-shaped region of the circuit pattern 26. In the example of FIG. 2, the plurality of semiconductor chips 40 is disposed in each of the island-shaped regions 26A and 26B. The plurality of semiconductor chips 40 disposed in one island-shaped region may be connected to the same island-shaped region by the lead frame 50. In the example of FIG. 2, the plurality of semiconductor chips 40 disposed in the island-shaped region 26A is connected in parallel to the same island-shaped region 26B by two lead frames 50 arranged in the Y axis direction. The plurality of semiconductor chips 40 disposed in the island-shaped region 26B is connected in parallel to the same island-shaped region 26C by two lead frames 50 arranged in the Y axis direction. In the two lead frames 50, a distance Y1 in the Y axis direction of the connecting portion connected to the same island-shaped region 26B or 26C may be smaller than a distance Y2 in the Y axis direction of the two semiconductor chips 40. This can consequently reduce the difference in the path length of the current passing through the two semiconductor chips 40 disposed apart from each other.

The semiconductor chip 40 of the present example is a vertical chip in which electrodes (for example, an emitter electrode and a collector electrode) are formed on an upper surface and a lower surface. The semiconductor chip 40 is connected to the circuit pattern 26 by an electrode formed in the lower surface, and is connected to the lead frame 50 by an electrode formed in the upper surface. Note that the semiconductor chip 40 is not limited to a vertical chip. The semiconductor chip 40 may have an electrode connected to the circuit pattern 26 in the upper surface. In this case, the circuit pattern 26 and the electrode may be connected by a wire or the like.

The terminal connecting portion 198 connects the circuit pattern 26 and the terminal 86 illustrated in FIG. 1. The terminal connecting portion 198 may be a plate or a rod-shaped member formed of metal, or may be a wire-shaped member. This allows consequently the electrical connection between the semiconductor chip 40 and the terminal 86.

FIG. 3 is a sectional view taken along line A-A of FIG. 2. FIG. 3 illustrates an arrangement example of each member when each member is projected on the XZ plane. In this side surface, the semiconductor module 100 includes the insulating board 20, the heat dissipation plate 22, a bonding layer 24, a cooling portion 16, the circuit pattern 26, the bonding layers 30, 32, and 34, the semiconductor chip 40, the lead frame 50, and the resin 12.

The heat dissipation plate 22 may cover at least a part or the whole of the lower surface of the insulating board 20. The bonding layer 24 bonds the heat dissipation plate 22 to the cooling portion 16. The bonding layer 24 is solder or the like. The cooling portion 16 contains a refrigerant such as water therein. The cooling portion 16 cools the semiconductor chip 40 via the heat dissipation plate 22 and the like.

The circuit pattern 26 is disposed in the upper surface of the insulating board 20. In the present example, the circuit pattern 26 may be formed of the same material as that of the heat dissipation plate 22 such as copper, or may be formed of a different material. The semiconductor chip 40 of the present example is connected to the upper surfaces of the island-shaped regions 26A and 26B of the circuit pattern 26 by the bonding layer 30. The bonding layer 30 bonds the semiconductor chip 40 with a conductive material such as solder.

The lead frame 50 of the present example connects the semiconductor chip 40 and the island-shaped regions 26B and 26C of the circuit pattern 26. The lead frame 50 of the present example includes a chip connecting portion 52, a circuit pattern connecting portion 56, and a bridge portion 54. The chip connecting portion 52 is a portion bonded to the upper surface of the semiconductor chip 40 by the bonding layer 32. The circuit pattern connecting portion 56 is a portion connected to the upper surfaces of the island-shaped regions 26B and 26C of the circuit pattern 26 by the bonding layer 34. The chip connecting portion 52 and the circuit pattern connecting portion 56 may be plate-shaped portions substantially parallel to the XY plane. Note that “substantially parallel” refers to, for example, a state where the angle is 10 degrees or less. In the present example, the area of the chip connecting portion 52 is configured to be larger than the area of the circuit pattern connecting portion 56. The area of the chip connecting portion 52 and the area of the circuit pattern connecting portion 56 may be, for example, the area of the upper surface of the plate-shaped portion connected to the semiconductor chip 40 and the island-shaped regions 26B and 26C of the circuit pattern 26.

The bridge portion 54 connects the chip connecting portion 52 and the circuit pattern connecting portion 56. The bridge portion 54 is disposed apart from the conductive member such as the circuit pattern 26. The bridge portion 54 of the present example is disposed above the circuit pattern 26 and the like, and is provided from the chip connecting portion 52 to the circuit pattern connecting portion 56 so as to straddle the circuit pattern 26 and the like.

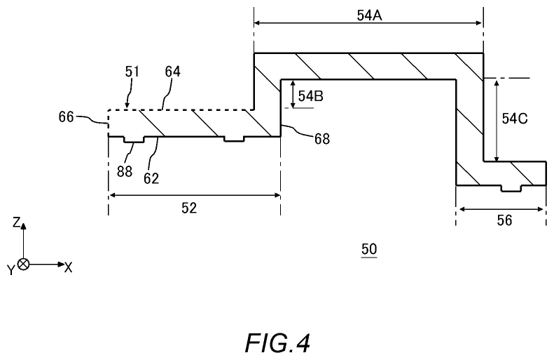

The bridge portion 54 may have a bridge surface 54A (see FIG. 4) that is a plate-shaped member substantially parallel to the XY plane. The bridge portion 54 may have a leg portion 54B (see FIG. 4) that connects the chip connecting portion 52 and the bridge surface 54A. The bridge portion 54 may have a leg portion 54C (see FIG. 4) connecting the bridge surface 54A and the circuit pattern connecting portion 56. The leg portion 54B and the leg portion 54C may be plate-shaped portions not parallel to the XY plane. For example, the leg portion 54B and the leg portion 54C may be formed so as to have an angle of 45 degrees or more with respect to the XY plane. The leg portion 54B and the leg portion 54C of the present example include a portion perpendicular to the XY plane.

The bridge portion 54 is provided with an opening 74 (see FIG. 2) for injecting the resin 12 below the bridge portion 54. The bridge portion 54 of the present example is provided with a plurality of openings 74 inside the bridge portion 54 in the XY plane and near the center of the bridge portion 54 in the X axis direction. The plurality of openings 74 may be provided in a region that is not near the center of the bridge portion 54 in the X axis direction. Note that the opening 74 is not limited to be provided in the bridge portion 54, but may be provided in another part of the lead frame 50 such as the chip connecting portion 52 and the circuit pattern connecting portion 56. This can consequently allow reliable distribution of the resin 12 above and below the lead frame 50.

The resin 12 is provided in an inner portion of the resin case 10. The resin 12 may be filled in the space 94 of resin case 10 such that semiconductor chip 40, lead frame 50, and circuit pattern 26 are not exposed.

In the semiconductor module 100 described above, the semiconductor chip 40 serves as a heat source, and the chip connecting portion 52 of the wiring connected to the semiconductor chip 40 repeats expansion and contraction due to temperature change. Since the resin 12 around the chip connecting portion 52 also repeats expansion and contraction due to temperature change, it is desirable to match the linear expansion coefficients of the wiring and the resin 12. However, even if the linear expansion coefficients are matched, an edge surface 66 of the chip connecting portion 52 is likely to peel off due to a difference in the temperature distribution and the contraction speed. Further, since the semiconductor chip 40 is a heat source, the chip connecting portion 52 has a higher risk of being repeatedly exposed to thermal stress than the circuit pattern connecting portion 56. In addition, in the present example, the area of the chip connecting portion 52 is configured to be larger than the area of the circuit pattern connecting portion 56. Also in this respect, the chip connecting portion 52 has a higher risk when exposed to thermal stress than the circuit pattern connecting portion 56.

Here, the leg portion 54B (see FIG. 4) is restrained by the resin 12 and hardly moves. Since the leg portion 54B acts as an axis, a portion that can be relatively fragile due to stress in the chip connecting portion 52 is considered to be the edge surface 66 (see FIG. 4). In other words, in the semiconductor module 100, a portion that can be relatively fragile due to stress is considered as the edge surface 66.

As the stress generated in the chip connecting portion 52 increases, the possibility that the chip connecting portion 52 and the resin are peeled off increases. When peeling occurs between the chip connecting portion 52 and the resin, there is a possibility that resin cracking may occur starting from this peeling. Therefore, in order to realize the semiconductor module 100 having high durability, it is preferable to prevent peeling from the resin and thus to suppress resin cracking starting from peeling by taking measures for the chip connecting portion 52, particularly the edge surface 66. Therefore, the semiconductor module 100 of the present example may have a configuration described below.

Description of Rough Surface Region 51

FIG. 4 is an enlarged view of the lead frame 50 of FIG. 3. The lead frame 50 has a rough surface region 51 in at least a part of the surface. In FIG. 4, the surface provided with the rough surface region 51 is indicated by a broken line. The rough surface region 51 is a region having a developed interfacial area ratio (Sdr) of 0.2 or more.

The developed interfacial area ratio represents an increase ratio of a surface area of a predetermined definition region to a projected area when projected on a predetermined plane in the predetermined definition region. For example, a completely flat definition region has a developed interfacial area ratio of 0 because the projected area and the surface area are equal. When the definition region has many irregularities, the projected area does not change, but the surface area increases, so that the developed interfacial area ratio increases. The developed interfacial area ratio of the rough surface region 51 may be 0.3 or more, or 0.4 or more.

Note that the arithmetic average height (Sa) of the rough surface region 51 may be 10 μm or less. The arithmetic average height is an average value of the heights or depths of the irregularities of the rough surface region 51 with respect to the surface obtained by averaging the heights of the rough surface region 51. That is, the rough surface region 51 is a region where the developed interfacial area ratio is increased by fine irregularities. The maximum height (Sz) of the rough surface region 51 may be 100 μm or less. The maximum height represents the distance from the highest point to the lowest point of each irregularity of the rough surface region 51.

The developed interfacial area ratio (Sdr), the arithmetic average height (Sa), and the maximum height (Sz) in the present embodiment may conform to the definition of ISO 25178 which is an international standard. Examples of the measurement environment of each parameter include the following. However, as a matter of course, it is also possible to use the values measured not only under this measurement environment but also under an equivalent measurement environment.

### (Example of Measurement Environment)

Measuring instrument: VK-X1100 manufactured by Keyence Corporation

Controller unit: VK-X1000 manufactured by Keyence Corporation

Objective lens: Apo ×50

Cutoff: Gaussian

S filter: None

L filter: None

F-operation: None

The rough surface region 51 can be formed by irradiating the lead frame 50 with a laser beam. In this case, the local rough surface region 51 can be easily formed with respect to the lead frame 50. The rough surface region 51 may be formed by injecting predetermined particles to a part or the whole of the lead frame 50, may be formed by immersing a part or the whole of the lead frame 50 in a predetermined solution, or may be formed by another method.

The rough surface region 51 may be provided in the chip connecting portion 52. In the semiconductor module 100, the semiconductor chip 40 serves as a heat source. For this reason, stress is likely to be applied to the chip connecting portion 52 connected to the semiconductor chip 40. When stress is applied to the lead frame 50, the lead frame 50 and the resin 12 are easily peeled off.

On the other hand, by providing the rough surface region 51 in the chip connecting portion 52, the contact area between the lead frame 50 and the resin 12 can be increased, so that peeling of the resin 12 can be suppressed. Locally providing the rough surface region 51 can easily reduce the manufacturing cost of the lead frame 50.

Among the surfaces of the chip connecting portion 52, a surface farthest from the bridge portion 54 (the leg portion 54B in the present example) is defined as the edge surface 66. Among the surfaces of the chip connecting portion 52, a surface facing the semiconductor chip 40, that is, bonded to the semiconductor chip 40 is defined as a lower surface 62, a surface on the opposite side to the lower surface 62 is defined as an upper surface 64, and a surface other than the edge surface 66 among the surfaces between the lower surface 62 and the upper surface 64 is defined as a side surface 68. The lower surface 62 and the upper surface 64 are surfaces substantially parallel to the XY plane. The edge surface 66 and the side surface 68 are surfaces not parallel to the XY plane. The edge surface 66 and the side surface 68 may be substantially perpendicular to the XY plane.

The rough surface region 51 is preferably provided on at least a part of the edge surface 66. As described above, this is because the edge surface 66 is a portion that can be relatively fragile, and peeling from the resin 12 easily occurs. Providing the rough surface region 51 in the edge surface 66 allows effective suppression of peeling between the lead frame 50 and the resin 12. The rough surface region 51 may be provided over half or more of the edge surface 66, or may be provided over the entire edge surface 66. When the rough surface region 51 is provided in a part of the edge surface 66, it is preferable to provide the rough surface region 51 in a portion of the edge surface 66 in contact with the lower surface 62. This is because the portion in contact with the lower surface 62 is a portion that may be in contact with the bonding layer 32 such as solder, and the bonding layer 32 made of solder or the like may generate a starting point of resin peeling. Providing the rough surface region 51 in this portion allows effective suppression of peeling of the resin 12.

The rough surface region 51 may be provided on at least a part of the upper surface 64. Providing the rough surface region 51 in the upper surface 64 allows further suppression of peeling between the lead frame 50 and the resin 12. The rough surface region 51 may be provided over half or more of the upper surface 64, or may be provided over the entire upper surface 64. When the rough surface region 51 is provided in a part of the upper surface 64, it is preferable to provide the rough surface region 51 in a portion of the upper surface 64 in contact with the edge surface 66.

The rough surface region 51 may be provided on at least a part of the side surface 68. Providing the rough surface region 51 in the side surface 68 allows further suppression of peeling between the lead frame 50 and the resin 12. The rough surface region 51 may be provided over half or more of the side surface 68, or may be provided over the entire side surface 68. When the rough surface region 51 is provided in a part of the side surface 68, the rough surface region 51 may be provided in a portion of the side surface 68 in contact with the edge surface 66. The rough surface region 51 may be provided in the side surface 68 in contact with a third side 83 described later. The rough surface region 51 may be provided in a portion of the side surface 68 in contact with the lower surface 62.

The rough surface region 51 may not be provided in the lower surface 62. This is because the lower surface 62 is connected to the semiconductor chip 40 via the bonding layer 32.

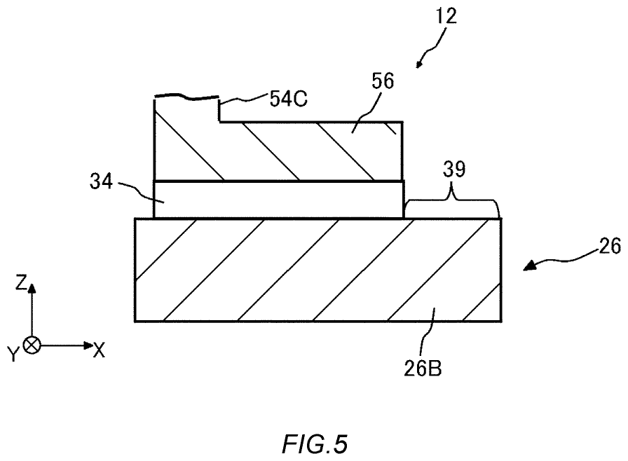

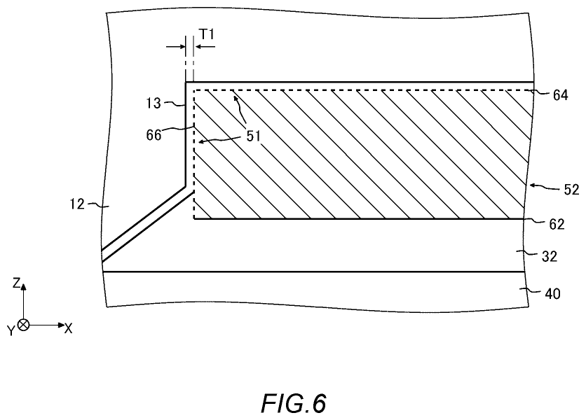

In the present example, the lower surface 62 of the chip connecting portion 52 is provided with a plurality of protrusions 88 protruding toward the insulating circuit board 160, that is, the semiconductor chip 40. Similarly, a plurality of protrusions 88 protruding toward the insulating circuit board 160, that is, the island-shaped regions 26B and 26C of the circuit pattern 26 may be provided also in the lower surface of the circuit pattern connecting portion 56. The length of the protrusion 88 in the X axis direction may be ¼ or less or ⅛ or less of the length of the chip connecting portion 52 or the circuit pattern connecting portion 56 in the X axis direction. The length of the protrusion 88 in the Y axis direction may be ¼ or less or ⅛ or less of the length of the chip connecting portion 52 or the circuit pattern connecting portion 56 in the Y axis direction. Providing the protrusion 88 allows the lower surface 62 of the chip connecting portion 52 or the circuit pattern connecting portion 56 to be disposed in parallel to the upper surface of the island-shaped regions 26B and 26C of the semiconductor chip 40 or the circuit pattern 26, and allows the bonding layer 32 made of solder or the like to be favorably formed. Note that, for easy understanding, the protrusion 88 is not illustrated in FIG. 3, FIG. 5, and FIG. 6.

FIG. 5 is an enlarged view of the vicinity of the circuit pattern connecting portion 56. As described above, the island-shaped regions 26B and 26C of the circuit pattern 26 are bonded to the circuit pattern connecting portion 56 of the lead frame 50 by the bonding layer 34. The developed interfacial area ratio in the rough surface region 51 of the chip connecting portion 52 may be larger than the developed interfacial area ratio in the circuit pattern 26. As an example, as the developed interfacial area ratio of the circuit pattern 26, a value of a region 39 in contact with the resin 12 may be used. The developed interfacial area ratio of the circuit pattern 26 is 0.08 or less. In FIG. 5, the developed interfacial area ratio of the island-shaped region 26B of the circuit pattern 26 has been described as an example, but the developed interfacial area ratios of the island-shaped regions 26A and 26C of the circuit pattern 26 may be similar.

The circuit pattern connecting portion 56 may or may not be provided with the rough surface region 51. The circuit pattern connecting portion 56 of the present example is not provided with the rough surface region 51. That is, the developed interfacial area ratio of each surface of the circuit pattern connecting portion 56 of the present example is smaller than the developed interfacial area ratio of the rough surface region 51 provided in the chip connecting portion 52. The developed interfacial area ratio on each surface of the circuit pattern connecting portion 56 may be smaller than 0.2. The developed interfacial area ratio of each surface of the circuit pattern connecting portion 56 may be 0.08 or less.

The rough surface region 51 may be provided in the entire surface of the lead frame 50. This may consequently facilitate processing of the lead frame 50.

FIG. 6 is an enlarged view of the vicinity of the edge surface 66 of FIG. 3. In the lead frame 50 of the present example, at least a part of the surface may be covered by a coating layer 13. The coating layer 13 is a thermoplastic high heat resistant film formed of a resin. The coating layer 13 may be formed by injecting the resin to each member with a sprayer or the like after bonding each member with solder or the like and before filling the resin 12. In another example, the coating layer 13 may be formed for each member before bonding the members with solder or the like. The coating layer 13 may be applied using a high-performance control dispensing apparatus (liquid fixed amount discharge apparatus). The coating layer 13 may be formed of a resin having higher heat resistance than the resin 12. The coating layer 13 may be formed of a resin having higher flexibility than the resin 12. The coating layer 13 is formed of, for example, a polyamide-based resin, a polyamideimide-based resin, or a polyimide-based resin, but the material is not limited thereto.

The coating layer 13 may be provided on a surface of the lead frame 50 other than the surface facing the semiconductor chip 40, or may be provided on the entire surface of the lead frame 50. The coating layer 13 preferably covers at least the rough surface region 51. In the chip connecting portion 52, the coating layer 13 may be applied so as to cover the edge surface 66, the upper surface 64, and the side surface 68. A film thickness T1 of the coating layer 13 is, for example, 1 μm or more and 100 μm or less. The film thickness T1 of the coating layer 13 may be preferably 2 μm or more, and more preferably 3 μm or more. Here, the film thickness T1 of the coating layer 13 may be an average thickness in a predetermined range. The surface of the coating layer 13 covering the rough surface region 51 may have irregularities corresponding to the irregularities of the rough surface region 51, and may be flatter than the rough surface region 51. Providing the coating layer 13 allows further suppression of peeling of the resin 12. The fact that the coating layer 13 is provided with irregularities corresponding to the irregularities of the rough surface region 51 means that the coating layer is disposed at a position where the concave portions of the rough surface region 51 and the concave portions of the coating layer 13 overlap each other and disposed at a position where the convex portions of the rough surface region 51 and the convex portions of the coating layer 13 overlap each other when viewed from a direction perpendicular to the rough surface region 51.

The coating layer 13 and the resin 12 may be bonded to each other by chemical bonding. Chemical, mechanical, and physical bonding between the coating layer 13 and the resin 12 can ensure strength therebetween.

Here, solder or the like of the bonding layer 32 may enter between the resin 12 and the lead frame 50. For example, when the lead frame 50 is bonded, solder or the like may crawl up the edge surface 66. When the coating layer 13 is applied and the resin 12 is filled after the lead frame 50 is bonded, adhesion between the bonding layer 32 made of solder or the like and the resin is not relatively good, so that the possibility that the resin (here, the coating layer 13) peels off from the bonding layer 32 starting from this portion increases. On the other hand, in the present example, since the adhesion between the resin and the lead frame 50 is increased by providing the rough surface region 51, even if the resin is peeled off from the bonding layer 32 by any chance, it is possible to suppress the resin from being peeled off also from the lead frame 50 due to the progress of the resin peeling.

The chip connecting portion 52 is a place where stress is likely to be applied as described above, and in other words, the chip connecting portion 52 is a portion that affects the durability against resin peeling of the semiconductor module 100. In the present example, the developed interfacial area ratio in the rough surface region 51 of the chip connecting portion 52 is made larger than the developed interfacial area ratio in the circuit pattern connecting portion 56. This can consequently increase the durability of the chip connecting portion 52 which has been a bottleneck. Making the developed interfacial area ratio of the chip connecting portion 52, which may be relatively fragile, larger than the developed interfacial area ratio of the circuit pattern connecting portion 56 means that processing or the like is not required for the circuit pattern connecting portion 56, so that an increase in cost can be suppressed without an increase in more steps than necessary.

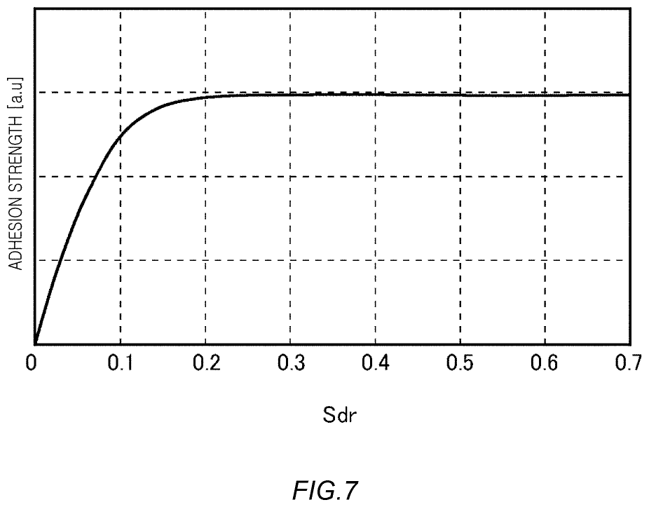

FIG. 7 is a diagram illustrating the relationship between the developed interfacial area ratio and the adhesion strength in the lead frame 50. In FIG. 7, the magnitude of the force when the resin is peeled off in a case where the force for separating the resin (here, the coating layer 13) from the lead frame 50 is increased is defined as the adhesion strength. In FIG. 7, the developed interfacial area ratio in each region of the lead frame 50 has been changed, and the adhesion strength in the region has been measured. Note that, in the present example, the experiment has been conducted under the condition that the arithmetic average height (Sa) of the rough surface region 51 is 10 μm or less, the maximum height (Sz) of the rough surface region 51 is 100 μm or less, and the irregularities do not vary extremely or the irregularities are not extremely high. Setting the arithmetic average height (Sa) and the maximum height (Sz) of the rough surface region 51 within the predetermined ranges in this manner allows the avoidance of the possibility of affecting the performance of other products.

As illustrated in FIG. 7, by setting the developed interfacial area ratio of each region of the lead frame 50 to 0.2 or more, the adhesion strength with the resin can be secured. Therefore, providing the lead frame 50 with the rough surface region 51 having a developed interfacial area ratio of 0.2 or more allows suppression of peeling of the resin 12. Note that an experiment has been conducted while the parameters to be changed have been also changed from the developed interfacial area ratio of the rough surface region 51 to the arithmetic average height (Sa) or the maximum height (Sz) of the rough surface region 51. However, in this case, it has been confirmed that the arithmetic average height (Sa) or the maximum height (Sz) has a small influence on the adhesion strength, and the developed interfacial area ratio of the rough surface region 51 is a parameter for ensuring the adhesion strength.

The lead frame 50 preferably has a structure that suppresses the solder or the like from crawling up in the edge surface 66. Hereinafter, a structure for suppressing the crawling-up of the solder or the like will be described.

Description of Step 70 or Inclination 90

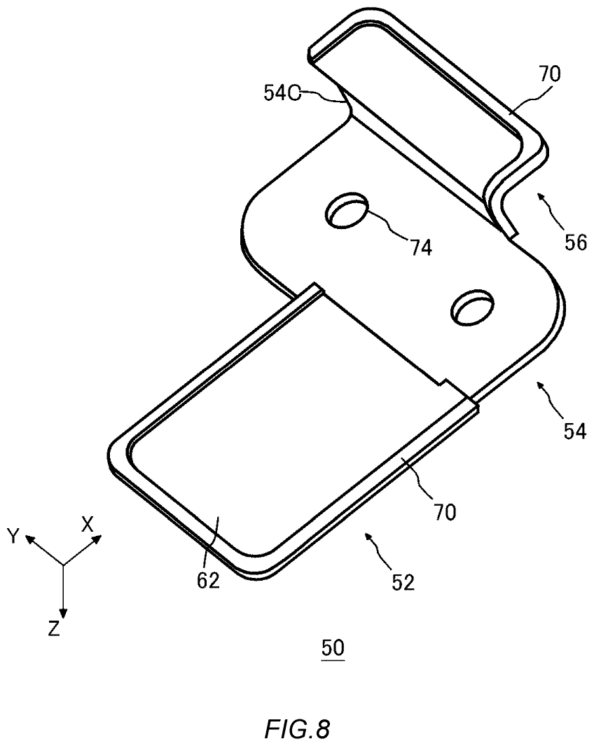

FIG. 8 is a perspective view illustrating another structural example of the lead frame 50. In the present example, in the chip connecting portion 52, a step 70 is preferably provided in the lower surface 62 facing the semiconductor chip 40. The step 70 similar to that of the chip connecting portion 52 may be provided also in the lower surface of the circuit pattern connecting portion 56. Note that, in the lead frame 50 of FIG. 8, the chip connecting portion 52 and the circuit pattern connecting portion 56 are not provided with the protrusion 88.

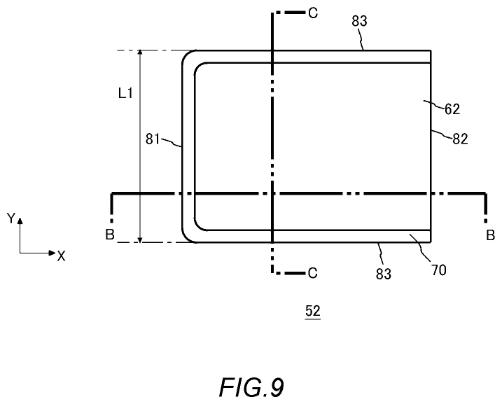

FIG. 9 is a diagram illustrating the lower surface 62 of the chip connecting portion 52 of FIG. 8. Among the sides constituting the outer shape of the lower surface 62, the side farthest from the bridge portion 54 is defined as a first side 81. In the present example, the lower surface 62 has a substantially rectangular shape having two sets of two sides parallel to each other, but may have another shape. The sides of the lower surface 62 may be straight lines. The first side 81 is connected to the edge surface 66. Among the sides of the lower surface 62, the side closest to the bridge portion 54 is defined as a second side 82. Among the sides of the lower surface 62, a side between the first side 81 and the second side 82 is defined as a third side 83. The third side 83 is connected to the side surface 68. The first side 81 and the third side 83 may be connected in a curved line.

The length of the first side 81 is referred to as L1. The first side 81 in the present example is a line extending in the Y axis direction. When lower surface 62 is rectangular, the length L1 is a distance between two third sides 83 in the Y axis direction. The lower surface 62 is provided with the step 70 along the first side 81 over a length of half or more of the first side 81. The state in which the step 70 is along a predetermined side may refer to a state in which the angle formed by the extending direction of the step 70 and the extending direction of the side is 15 degrees or less, may refer to a state in which the angle is 5 degrees or less, or may refer to a state in which the angle is 0 degrees.

The step 70 may be in contact with the first side 81. The distance between the step 70 and the first side 81 may be half or less of the distance between the first side 81 and the second side 82 in the X axis direction, or may be ¼ or less, or may be 1/10 or less. The step 70 may be ½ or greater than, or ¾ or greater than the length of first side 81 in the Y axis direction. The step 70 may be provided over the entire first side 81. This can consequently suppress the bonding layer 32 made of solder or the like from crawling up in the edge surface 66 to which stress is most likely to be applied.

The step 70 may be provided along the third side 83. The lower surface 62 may be provided with the step 70 along the third side 83 over a length of half or more of the third side 83. The step 70 may be in contact with the third side 83. The distance between the step 70 and the third side 83 may be half or less of the length L1, may be ¼ or less, or may be 1/10 or less. The step 70 may be provided over a length of ½ or more or ¾ or more of the length of the third side 83 in the X axis direction. The step 70 may be provided over the entire third side 83. This can consequently suppress the bonding layer 32 made of solder or the like from crawling up in the side surface 68.

The step 70 may or may not be provided in the second side 82. In the present example, the step 70 is not provided in the entire second side 82. The step 70 may be provided along a side other than the second side 82 among the sides of the lower surface 62. When the amount of solder or the like of the bonding layer 32 is excessive, the solder or the like protrudes from the second side 82, so that such a configuration can suppress the solder or the like from protruding to the edge surface 66 or the like.

As will be described later, the above-described step 70 may be inclined. That is, an inclination of ½ or more or ¾ or more of the length of the first side 81 in the Y axis direction along the first side 81 may be provided. An inclination of ½ or more or ¾ or more of the length of the third side 83 in the X axis direction along the third side 83 may be provided.

The step 70 includes at least one of a protrusion and a groove. As in the example illustrated in FIG. 8, the protrusion protrudes from the lower surface 62 toward the semiconductor chip 40. The groove is recessed from the lower surface 62 in a direction apart from the semiconductor chip 40. The side wall of the step 70 may be perpendicular to the lower surface 62, or may have a tapered shape having an angle with respect to the lower surface 62.

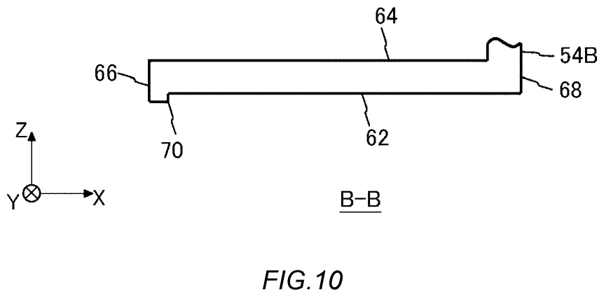

FIG. 10 is a diagram illustrating a cross section B-B in FIG. 9. The cross section B-B is an XZ cross section. The step 70 in the present example is a protrusion, but may be a groove. The step 70 is disposed along the edge surface 66.

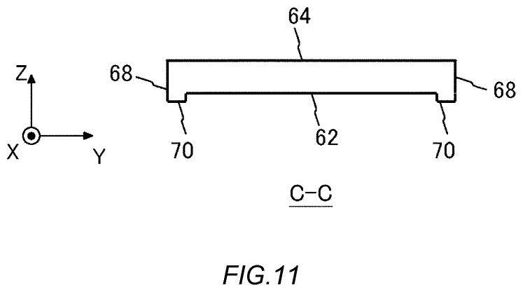

FIG. 11 is a diagram illustrating a cross section C-C in FIG. 9. The cross section C-C is a YZ cross section. The step 70 is disposed along the side surface 68 connected to the edge surface 66.

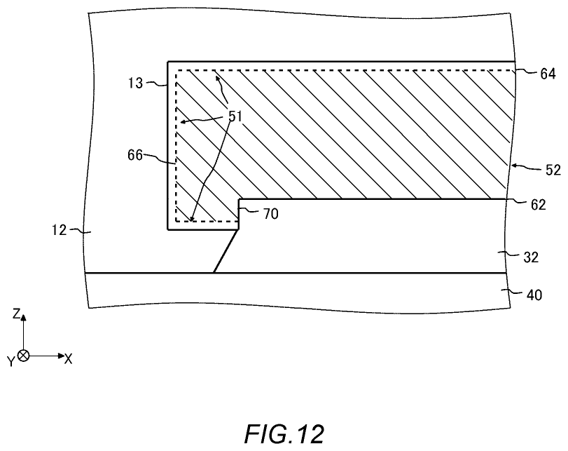

FIG. 12 is an enlarged view of the vicinity of the edge surface 66 when the lead frame 50 of FIG. 8 is applied. The step 70 in the present example is a protrusion disposed in contact with the edge surface 66. The height (or depth) of the step 70 in the Z axis direction with respect to the lower surface 62 may be half or less of the thickness of the chip connecting portion 52 in the Z axis direction, or may be ¼ or less. As illustrated in FIG. 12, providing the step 70 allows the position of the end portion of the bonding layer 32 made of solder or the like to be easily defined. That is, the position of the end portion of the bonding layer 32 easily coincides with the position of the end portion of the step 70. This can consequently suppress the bonding layer 32 from crawling up the edge surface 66 and the like.

The lead frame 50 having the step 70 may or may not be provided with the rough surface region 51. The lead frame 50 may be covered by the coating layer 13 or may not be covered.

In the present example, the rough surface region 51 is also provided in at least a part of the region where the step 70 is provided in the lower surface 62 of the lead frame 50. The rough surface region 51 may be provided over the entire step 70. This can consequently further suppress peeling of the resin 12. At least a part of the region of the lower surface 62 where the step 70 is provided may be covered with the coating layer 13.

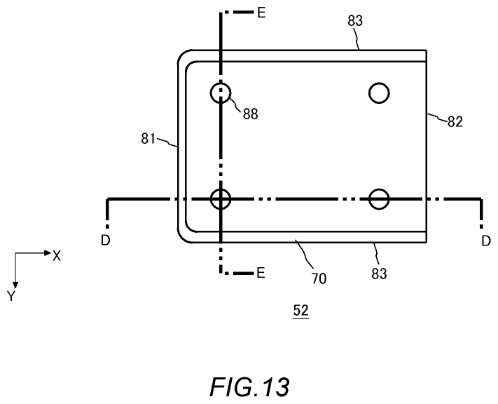

FIG. 13 is a diagram illustrating another example of the lower surface 62 of the chip connecting portion 52. The step 70 in the present example is a groove disposed in contact with the edge surface 66. The other structures of the step 70 are similar to those of the step 70 described with reference to FIG. 9 to FIG. 12. Also in the present example, the step 70 is provided along the first side 81 and the third side 83. Specifically, the step 70 is provided in contact with the first side 81 and the third side 83. Note that the step 70 may be in contact with each side or may be apart from each side.

In the present example, the plurality of protrusions 88 is provided in the lower surface 62 of the chip connecting portion 52. Each length of the protrusion 88 in the X axis and Y axis directions is shorter than that of the step 70. The length of the protrusion 88 in the X axis direction may be ¼ or less or ⅛ or less of the length of the chip connecting portion 52 in the X axis direction. The length of the protrusion 88 in the Y axis direction may be ¼ or less or ⅛ or less of the length of the chip connecting portion 52 in the Y axis direction. The protrusion 88 is lower in height in the Z axis direction than the step 70. Providing the protrusion 88 allows the distance between the semiconductor chip 40 and the chip connecting portion 52 to be maintained.

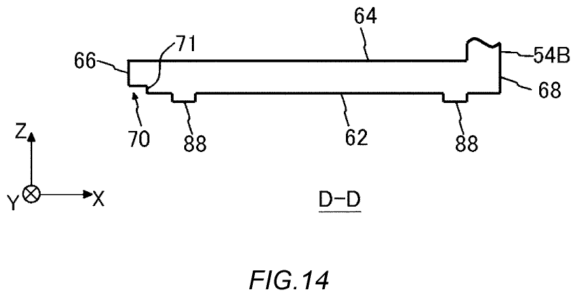

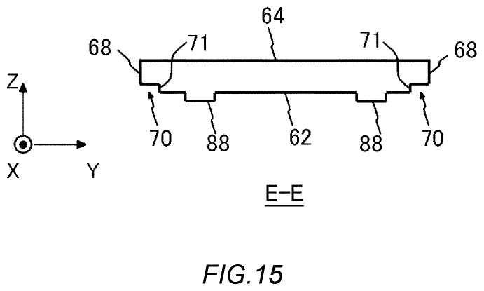

FIG. 14 is a diagram illustrating a cross section D-D in FIG. 13. The cross section D-D is an XZ cross section. FIG. 15 is a diagram illustrating a cross section E-E in FIG. 13. The cross section E-E is a YZ cross section. The step 70 is disposed along the edge surface 66 and the side surface 68 connected to the edge surface 66. This can consequently form a fillet (skirt portion) of the bonding layer 32 made of solder or the like in a retraction surface 71 of the step 70 which is a groove, and suppress the solder or the like from crawling up in the edge surface 66 and the side surface 68.

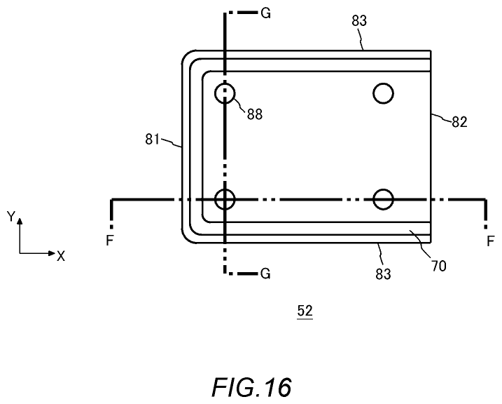

FIG. 16 is a diagram illustrating another example of the lower surface 62 of the chip connecting portion 52. The step 70 in the present example is a groove disposed apart from the edge surface 66 and the side surface 68 connected to the edge surface 66. The other structures of the step 70 are similar to those of the step 70 described with reference to FIG. 9 to FIG. 15. Also in the present example, the step 70 is provided along the first side 81 and the third side 83. The step 70 may be in contact with or apart from each side. In the present example, the step 70, which is a groove, is provided apart from the first side 81 and the third side 83. The plurality of protrusions 88 is provided in the lower surface 62 of the chip connecting portion 52.

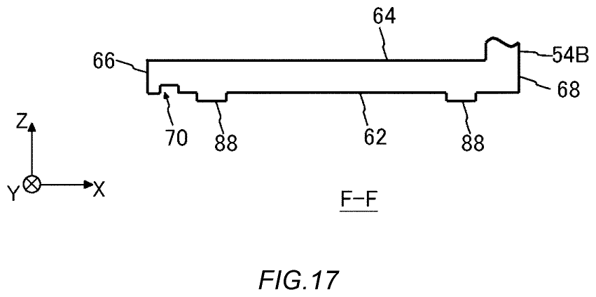

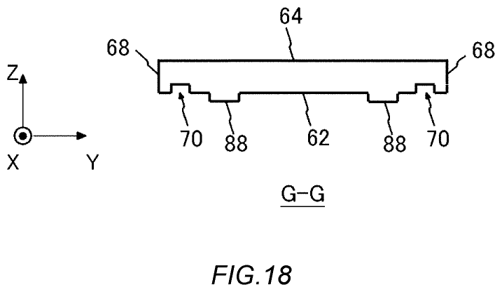

FIG. 17 is a diagram illustrating a cross section F-F in FIG. 16. The cross section F-F is an XZ cross section. FIG. 18 is a diagram illustrating a cross section G-G in FIG. 16. The cross section G-G is a YZ cross section. The step 70 is disposed along the edge surface 66 and the side surface 68 connected to the edge surface 66. The step 70 is disposed between the protrusion 88 and the edge surface 66 or between the protrusion 88 and the side surface 68 connected to the edge surface 66. Since the bonding layer 32 made of solder or the like is accommodated in the step 70 which is a groove, and a fillet made of solder or the like is formed starting therefrom, it is possible to suppress the solder or the like from crawling up in the edge surface 66 and the side surface 68.

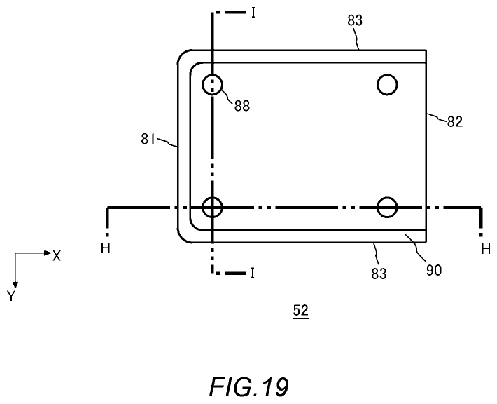

FIG. 19 is a diagram illustrating another example of the lower surface 62 of the chip connecting portion 52. In the present example, an inclination 90 is provided in the lower surface 62 of the chip connecting portion 52. The inclination 90 is inclined at a predetermined angle so as to be apart from the semiconductor chip 40 toward the outside of the lower surface 62. The other structures are similar to those of the chip connecting portion 52 described above. The protrusion 88 may have a height in the Z axis direction lower than the inclination 90.

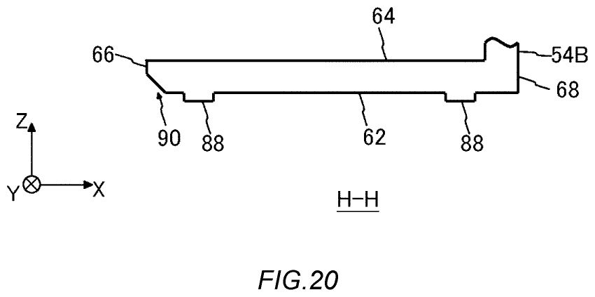

FIG. 20 is a diagram illustrating a cross section H-H in FIG. 19. The cross section H-H is an XZ cross section. The inclination 90 is disposed in contact with the edge surface 66. Specifically, the inclination 90 is provided from the lower surface 62 to the edge surface 66. That is, the inclination 90 is formed by chamfering a corner portion of the lower surface 62, that is, a corner connecting the lower surface 62 and the edge surface 66. The angle between the inclination 90 and the lower surface 62 may be 20 degrees or more and 70 degrees or less.

Providing the tapered inclination 90 allows the fillet of the bonding layer 32 to be stabilized in a shape corresponding to the angle of the inclination 90. Therefore, the shape of the fillet of the bonding layer 32 can be stabilized. Therefore, it is possible to suppress peeling of the resin caused by a variation in the fillet shape of the bonding layer 32. Since the inclination 90 can be formed by chamfering corners, processing is easy.

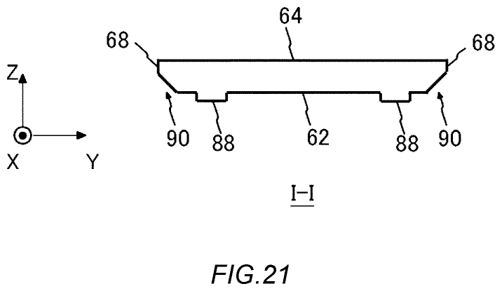

FIG. 21 is a diagram illustrating a cross section I-I in FIG. 19. The cross section I-I is a YZ cross section. The inclination 90 is disposed in contact with the side surface 68 connected to the edge surface 66. Similarly to the example of FIG. 20, the inclination 90 has an angle with respect to the lower surface 62. The inclination 90 is provided from the lower surface 62 to the side surface 68 connected to the edge surface 66. That is, the inclination 90 is formed by chamfering the corner portion of the lower surface 62, that is, the corner between the lower surface 62 and the side surface 68 connected to the edge surface 66. The angle between the inclination 90 and the lower surface 62 may be 20 degrees or more and 70 degrees or less. This can consequently stabilize the fillet shape of the bonding layer 32. In the present example, the inclination 90 is inclined at a predetermined angle so as to be apart from the semiconductor chip 40 toward the outside of the lower surface 62, but may be formed so as to approach the semiconductor chip 40 toward the outside of the lower surface 62.

Description of Inhibition Region 251

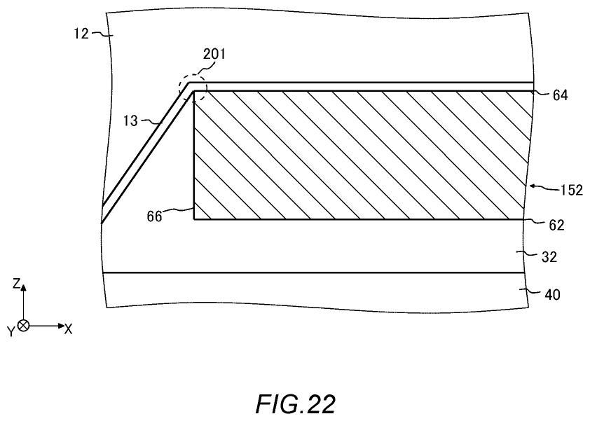

FIG. 22 is a diagram illustrating the chip connecting portion 152 according to a reference example. The chip connecting portion 152 has the same structure as that of the chip connecting portion 52 except that the rough surface region 51 is not provided. The edge surface 66 or the side surface 68 of the chip connecting portion 152 has solder wettability. Therefore, the solder 32 may crawl up along the edge surface 66 or the side surface 68.

When the coating layer 13 is formed after the solder 32 crawls up along the edge surface 66 or the side surface 68, the solder 32 is interposed between the coating layer 13 and the edge surface 66 or the side surface 68 of the chip connecting portion 152. The bonding force between the coating layer 13 and the solder 32 is relatively weak. For this reason, the coating layer 13 may be peeled off due to thermal stress or the like. As illustrated in FIG. 22, when the solder 32 crawls up to the vicinity of a vertex 201 of the edge surface 66, the area where the chip connecting portion 52 and the edge surface 66 or the like are in contact with each other is reduced, and thus the coating layer 13 is more easily peeled off. When peeling of the coating layer 13 progresses, cracks may occur in the resin 12.

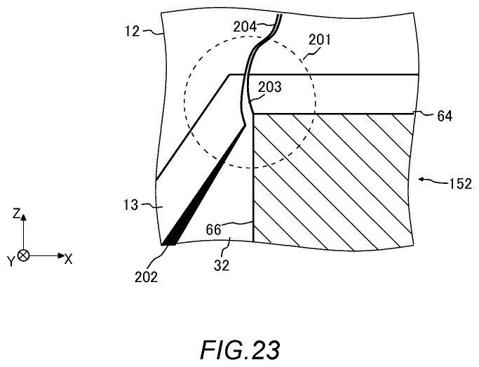

FIG. 23 is an enlarged view of the vicinity of the vertex 201 of the chip connecting portion 152. As described above, when the solder 32 crawls up to the vicinity of the vertex 201, the coating layer 13 may peel off in the vicinity of the vertex 201. FIG. 23 illustrates a space 202 generated by peeling of the coating layer 13.

When the peeling of the coating layer 13 further progresses, the adhesion strength between the solder 32 and the coating layer 13 is insufficient, so that the solder 32 is likely to move due to thermal stress, and a crack 203 may occur in the coating layer 13. When the crack 203 reaches the resin 12, a crack 204 may also occur in the resin 12. When the crack 204 occurs, the lead frame 50, the semiconductor chip 40, and the like cannot be sufficiently protected.

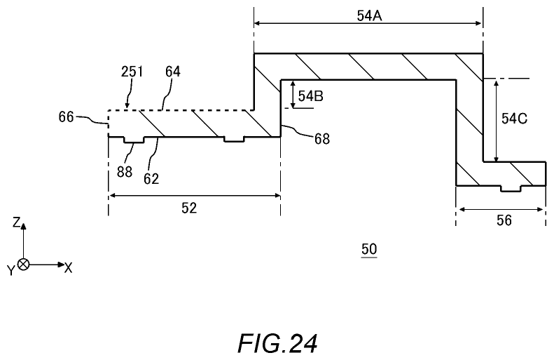

FIG. 24 is a diagram illustrating another example of the lead frame 50. The lead frame 50 of the present example includes an inhibition region 251 in the surface of the chip connecting portion 52 instead of the rough surface region 51 described in FIG. 1 to FIG. 21. The structure other than the inhibition region 251 may be the same as any of the structures described in FIG. 1 to FIG. 21.

The inhibition region 251 inhibits wet-spreading of the solder. That is, the inhibition region 251 is a region having solder wettability lower than the surface of the lead frame 50 where the inhibition region 251 is not provided. The solder wettability may be indicated by a size of an area obtained by projecting a region where solder spreads on a plane when a predetermined mass of solder is placed on a target surface and heated under a predetermined condition. The solder wettability may be indicated by a height at which the solder crawls up the vertically disposed target surface when a predetermined mass of solder is disposed at the lower end of the target surface and heated under a predetermined condition.

The inhibition region 251 is provided at least in the edge surface 66 of the chip connecting portion 52. The inhibition region 251 may be provided in a partial region of the edge surface 66, or may be provided in the entire edge surface 66. This can consequently suppress the solder from crawling up in the edge surface 66 where the thermal stress is most likely to concentrate, and suppress peeling of the coating layer 13. The inhibition region 251 may also be provided on at least one side surface 68 of the chip connecting portion 52. The inhibition region 251 may be provided on each side surface 68. The inhibition region 251 may be provided in a partial region of the side surface 68 or may be provided in the entire side surface 68. The inhibition region 251 may also be provided in the upper surface 64 of the chip connecting portion 52. The inhibition region 251 may be provided in a partial region of the upper surface 64, or may be provided in the entire upper surface 64. The inhibition region 251 may or may not be provided also in the circuit pattern connecting portion 56. In the example of FIG. 24, the inhibition region 251 is not provided in the circuit pattern connecting portion 56. The inhibition region 251 may be provided in the entire surface of the lead frame 50.

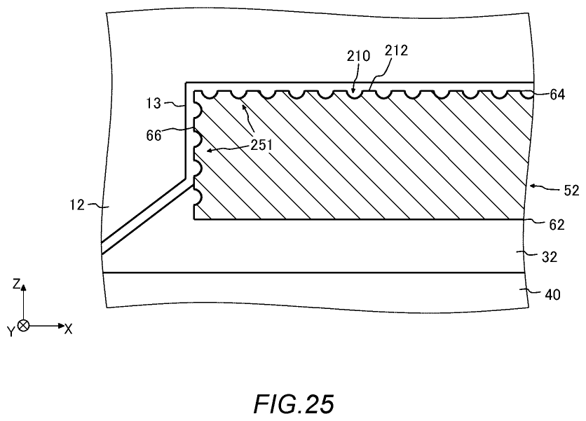

FIG. 25 is an enlarged view of the vicinity of the edge surface 66 of the chip connecting portion 52. In FIG. 25, the inhibition region 251 provided in the edge surface 66 and the upper surface 64 is illustrated, and the inhibition region 251 of the side surface 68 is omitted.

The inhibition region 251 of the present example is a region in which a plurality of concave portions 210 and a plurality of flat portions 212 are formed in the surface of the lead frame 50. Providing the plurality of concave portions 210 in the surface of the lead frame 50 allows a step to be formed in the surface of the chip connecting portion 52 so as to suppress the solder 32 from wet-spreading.

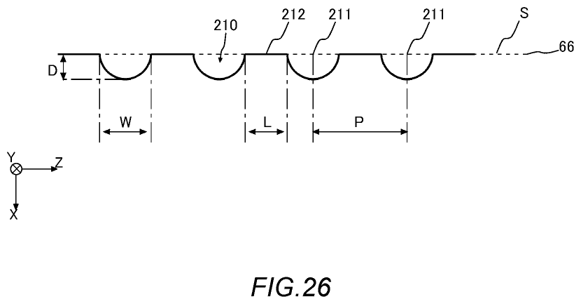

FIG. 26 is a diagram illustrating an example of the concave portion 210 and the flat portion 212 in the edge surface 66. Note that the inhibition region 251 formed on the other surface may also have a structure similar to that of the inhibition region 251 of the edge surface 66. The concave portion 210 is a portion recessed from a surface S of the edge surface 66. The flat portion 212 is a remaining portion of the edge surface 66 where the concave portion 210 is not formed. The plurality of flat portions 212 may be disposed on the same plane (on the surface S in FIG. 26).

The flat portion 212 is disposed between the two concave portions 210 adjacent to each other in a predetermined direction. The plurality of concave portions 210 may be disposed two-dimensionally in the edge surface 66. The plurality of concave portions 210 may be periodically disposed along at least two directions. The period (or interval) of the concave portions 210 in one direction may be constant or may not be constant. FIG. 26 illustrates the concave portions 210 and the flat portion 212 disposed at regular intervals in the height direction (Z axis direction).

A maximum width W of each concave portion 210 may be 10 μm or more. The maximum width W refers to a width which is maximum among the widths of the concave portions 210 in the surface S. For example, when the shape of the concave portion 210 in the surface S is a circle, the maximum width W is the diameter of the concave portion 210 in the surface S. When the shape of the concave portion 210 in the surface S is a square, the maximum width W is a diagonal length of the concave portion 210 in the surface S. Enlarging the concave portion 210 allows the solder to be stored in the concave portion 210, which can suppress wet-spreading of the solder. The maximum width W may be 15 μm or more, 20 μm or more, or 30 μm or more.

A depth D of each concave portion 210 may be 1 μm or more. The depth D refers to the maximum depth of the concave portion 210 with respect to the surface S. Increasing the depth D allows the step in the surface S to be increased, and the volume of the concave portion 210 to be increased. This can consequently suppress wet-spreading of the solder. The depth D may be 3 μm or more, 5 μm or more, or 10 μm or more. Note that the depth D may be smaller than the maximum width W or may be smaller than a half of the maximum width W.

An interval P of the centers 211 of the adjacent concave portions 210 may be 10 μm or more. The center 211 is the center of the concave portion 210 in the surface S. The center 211 may refer to the center of gravity of the geometric shape of the concave portion 210 in the surface S. If the interval P becomes too small, wet-spreading of the solder cannot be suppressed. For example, when the interval P is smaller than the maximum width W, the concave portions 210 overlap each other. In this case, the solder easily spreads over the plurality of overlapping concave portions 210. The interval P is preferably larger than the maximum width W. The interval P may be larger than the maximum width W by 1 μm or more, 3 μm or more, or 5 μm or more. A length L of the flat portion 212 may be 1 μm or more. The length L is the shortest distance between two adjacent concave portions 210. The length L may be 3 μm or more, or may be 5 μm or more. Note that both the interval P and the length L may be larger than the depth D.

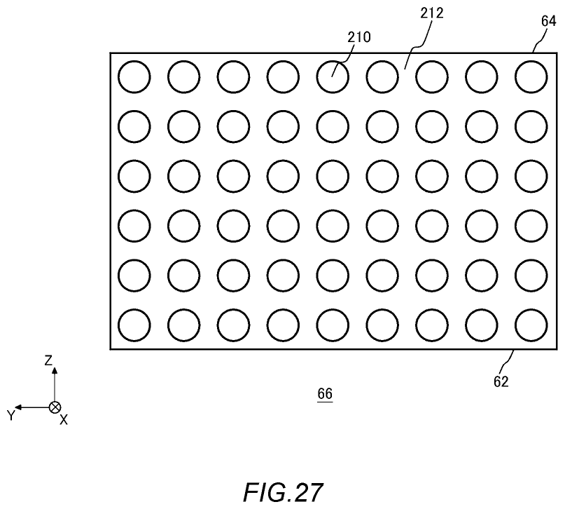

FIG. 27 is a diagram illustrating an arrangement example of the concave portions 210 and the flat portion 212 in the edge surface 66. Note that, in each drawing, the number of concave portions 210 disposed in the edge surface 66 is an example, and the number of concave portions 210 is not limited to the illustrated example.

The concave portions 210 are periodically disposed in at least two directions of the edge surface 66. In the example of FIG. 27, the concave portions are disposed periodically in two direction of a lateral direction (Y axis direction) parallel to the lower surface 62 of the chip connecting portion 52 and the height direction (Z axis direction) perpendicular to the lower surface 62. The lateral direction and the height direction are directions perpendicular to each other.

The flat portion 212 is disposed between two concave portions 210 adjacent to each other in an arbitrary direction. In the example of FIG. 27, a region where the concave portion 210 is not formed in the edge surface 66 is the flat portion 212. For example, the flat portion 212 is disposed between two concave portions 210 adjacent to each other in the lateral direction and between two concave portions 210 adjacent to each other in the height direction. The flat portions 212 in the edge surface 66 may be connected to each other.

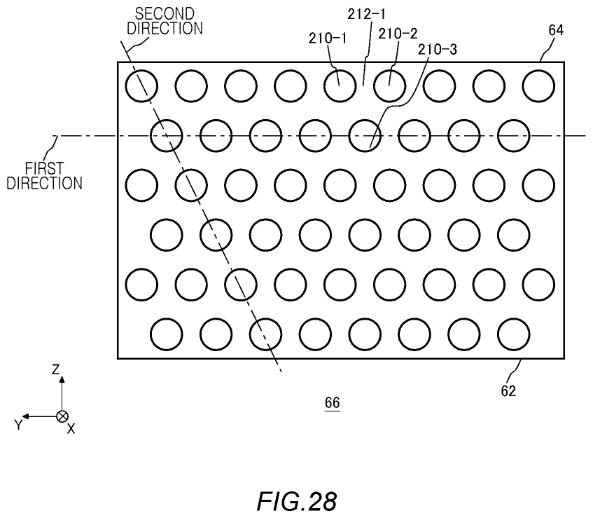

FIG. 28 is a diagram illustrating another arrangement example of the concave portions 210 and the flat portion 212 in the edge surface 66. The edge surface 66 of the present example is different from the example of FIG. 27 in the direction in which the concave portions 210 are periodically disposed. The other structures are similar to those of the example of FIG. 27.

The concave portions 210 are periodically disposed along a first direction and a second direction. In the example of FIG. 27, the first direction and the second direction are orthogonal to each other. In the present example, the first direction and the second direction obliquely intersect. As an example, the first direction is the Y axis direction, and the second direction is a direction obliquely intersecting the Y axis.

The plurality of concave portions 210 is disposed with a predetermined gap in the lateral direction (Y axis direction) parallel to the lower surface 62 of the chip connecting portion 52. The flat portion 212 may be disposed in the gap. In the example of FIG. 28, a flat portion 212-1 is disposed between a concave portion 210-1 and a concave portion 210-2.

The plurality of concave portions 210 includes a concave portion 210-3 disposed side by side with the gap (flat portion 212-1) in the height direction (Z axis direction). The concave portion 210-3 is the concave portion 210 adjacent to the concave portion 210-1 in the second direction. The concave portion 210-3 may be disposed at the center between the concave portion 210-1 and the concave portion 210-2 in the lateral direction (Y axis direction).

According to the present example, the flat portion 212 is prevented from being disposed in a straight line in the Z axis direction from the lower surface 62 to the upper surface 64. Therefore, it is possible to suppress the solder from crawling up from the lower surface 62 to the upper surface 64 at the shortest distance. In the lateral direction (Y axis direction), the width of the concave portion 210 is preferably larger than the width of the gap (flat portion 212-1). The width of the gap (flat portion 212-1) is the shortest distance between the two concave portions 210-1 and 210-2 sandwiching the gap in the lateral direction.

Method of Manufacturing Rough Surface Region 51 and Inhibition Region 251; Description of Laser Roughening

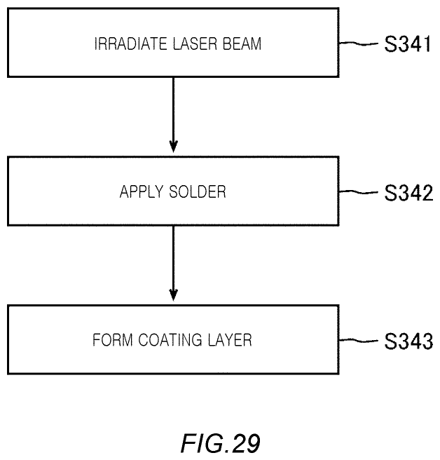

FIG. 29 is a diagram illustrating some steps in the method of manufacturing the semiconductor module 100. In the present example, the surface of the chip connecting portion 52, specifically, at least the edge surface 66 is irradiated with a laser beam to form the plurality of concave portions 210 and the flat portion 212 (S341). In Step S341, a plurality of concave portions 210 and the flat portion 212 may also be formed on each side surface 68 and the upper surface 64.

Next, the lead frame 50 is soldered to the semiconductor chip 40 by the solder 32 (S342). Since the concave portions 210 and the flat portion 212 are formed in the edge surface 66 and the like before Step S342, it is possible to suppress the solder 32 from crawling up in the edge surface 66 and the like.

Next, the coating layer 13 is formed (S343). In Step S343, the coating layer 13 may be formed in the surfaces of the lead frame 50 and the solder 32. After Step S343, the lead frame 50, the semiconductor chip 40, and the like may be sealed with the resin 12. This can consequently form the semiconductor module 100.

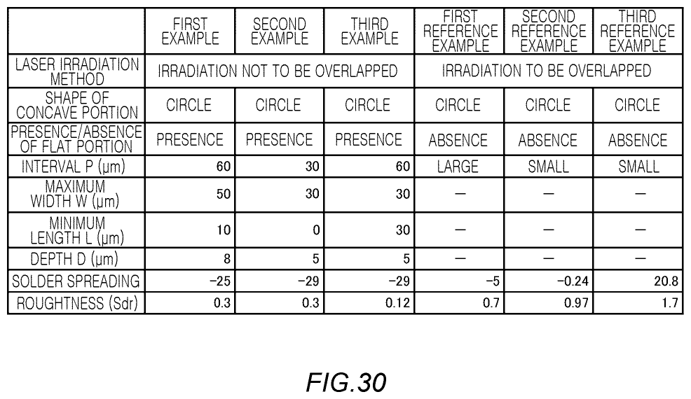

FIG. 30 is a diagram illustrating measurement results of first to third examples and first to third reference examples. In the present first to third examples, the surface of the chip connecting portion 52 is irradiated such that the laser beams are not overlapped, that is, the plurality of concave portions 210 and the flat portion 212 disposed between the two concave portions 210 are formed. In the second example, since the shape of the concave portion 210 is a circle, the flat portion 212 is generated between the circles even if the interval P and the maximum width W are the same. As described above, the length L is the shortest distance between the two adjacent concave portions 210, in other words, the minimum length L. Therefore, the length in the Z axis direction between the circles is not constant, and the flat portion 212 is generated in a portion that is not the shortest distance. In the first to third reference examples, the laser beams are superimposed in the surface of the chip connecting portion 52. Specifically, in the first to third reference examples, the laser beams are superimposed so that the flat portion 212 is not formed between the two concave portions 210. In the first reference example, the interval P of laser irradiation at the time of superimposition is larger than that in the second reference example and the third reference example.

The solder spreading in FIG. 30 is an index indicating the area where the solder has spread. In FIG. 30, the solder spreading of the edge surface 66 in which the concave portion 210 is not formed is set to 0. The degree of spreading when solder spreading is larger than that of the edge surface 66 in which the concave portion 210 is not formed is indicated by a positive numerical value, and the degree of spreading when solder expansion is small is indicated by a negative numerical value. As illustrated in FIG. 30, in the first to third examples in which the flat portion 212 is provided between the two concave portions 210, solder spreading tends to be smaller than that when the concave portion 210 is not formed. In the first to third examples in which the flat portion 212 is provided between the two concave portions 210, solder spreading tends to be smaller than that in the first to third reference examples in which only the concave portion 210 is provided without forming the flat portion 212.

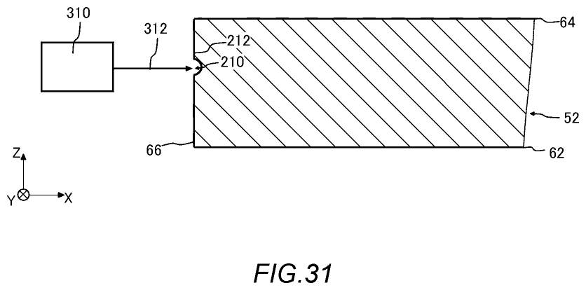

Note that the lead frame 50 described in the examples of FIG. 24 to FIG. 29 may have the rough surface region 51 described in FIG. 1 to FIG. 23. The edge surface 66 may have the rough surface region 51, the side surface 68 may have the rough surface region 51, and the upper surface 64 may have the rough surface region 51. The inhibition region 251 described in FIG. 24 to FIG. 29 may function as the rough surface region 51. That is, the developed interfacial area ratio of the inhibition region 251 may be 0.2 or more. The entire edge surface 66 may have a developed interfacial area ratio of 0.2 or more. The rough surface region 51 may be formed in the flat portion 212. For example, after the rough surface region 51 is formed in the edge surface 66, the plurality of concave portions 210 may be formed by laser irradiation or the like. The above configuration similarly applies to the lead frame 50 of FIG. 31 to FIG. 45 described below.

In the first and second examples, the developed interfacial area ratio of the inhibition region 251 is 0.2 or more, and functions as the rough surface region 51. Therefore, wet-spreading of the solder can be inhibited, and adhesion between the resin such as the coating layer 13 and the lead frame 50 can be increased.

Note that, as illustrated in FIG. 25, at least some of the concave portions 210 in the edge surface 66 may be in contact with the solder 32. Forming the concave portion 210 in the region in contact with the solder 32 can suppress the crawling-up of the solder 32. In at least some of the concave portions 210, the solder 32 (bonding layer 32) may be provided in an inner portion of the concave portion 210. Some of the concave portions 210 in the edge surface 66 may be in contact with the coating layer 13. The concave portion 210 closest to the upper surface 64 may be in contact with the coating layer 13, and the concave portion 210 closest to the lower surface 62 may be in contact with the solder 32.

FIG. 31 is a diagram for explaining laser irradiation to the chip connecting portion 52. FIG. 31 schematically illustrates the vicinity of the edge surface 66 of the chip connecting portion 52 and a light source 310. In the present example, the light source 310 irradiates the surface of the chip connecting portion 52 with a laser beam 312. One concave portion 210 can be formed by irradiating the surface of the chip connecting portion 52 with the laser beam 312 once. The remaining surface on which the concave portion 210 is not formed becomes the flat portion 212. In FIG. 31, the edge surface 66 is irradiated with a laser beam to form one concave portion 210 and the flat portion 212.

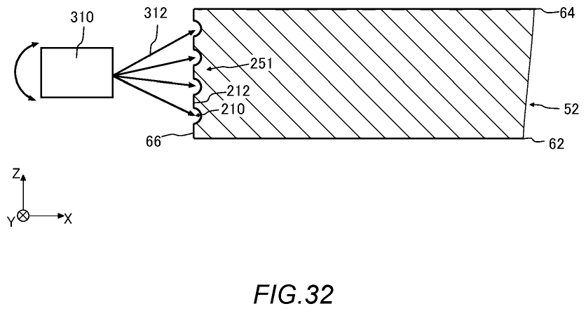

FIG. 32 is a diagram illustrating an example of laser irradiation in Step S341 of FIG. 29. In Step S341, the light source 310 irradiates the surface of the chip connecting portion 52 with the laser beam 312 without replacing the chip connecting portion 52. That is, in the present example, the arrangement of the chip connecting portion 52 is fixed. Then, by changing the laser irradiation angle of the light source 310, the laser beam 312 is irradiated to a plurality of positions on the surface of the chip connecting portion 52. The light source 310 sequentially irradiates the surface of the chip connecting portion 52 with a plurality of laser beams 312. This can consequently form the plurality of concave portions 210 and the flat portion 212 disposed between the two concave portions 210 in the surface of the chip connecting portion 52, and provide the inhibition region 251 in the surface of the chip connecting portion 52. In the present example, the plurality of concave portions 210 and the flat portion 212 disposed between the two concave portions 210 are formed in the surface of the edge surface 66. The light source 310 may perform irradiation with the plurality of laser beams 312 without changing the focal position. In the present example, the focal position may be adjusted to any position of the edge surface 66. The shape or size of each concave portion 210 may be different.

In the present example, the plurality of concave portions 210 and the flat portion 212 disposed between the two concave portions 210 are formed in the surface of the edge surface 66, but the plurality of concave portions 210 and the flat portion 212 disposed between the two concave portions 210 may be formed in the surface of the upper surface 64. In this case, by forming the plurality of concave portions 210 and the flat portion 212 disposed between the two concave portions 210 in the surface of the edge surface 66 and replacing the chip connecting portion 52, the plurality of concave portions 210 and the flat portion 212 disposed between the two concave portions 210 can be formed in the surface of the upper surface 64. Note that replacing the chip connecting portion 52 means changing the relative position of each surface of the chip connecting portion 52 with respect to the light source 310. The surface of the chip connecting portion 52 may be irradiated with the laser beam 312 by a plurality of light sources 310. For example, one light source 310 irradiates the surface of the edge surface 66 with the laser beam 312, and another light source 310 irradiates the surface of the upper surface 64 with the laser beam 312. Even in such a configuration, the inhibition region 251 can be provided in the surface of the edge surface 66 and the surface of the upper surface 64. Although the light source 310 in FIG. 32 changes the irradiation angle in the XZ plane, the light source 310 may change the irradiation angle in the YZ plane. That is, although the light source 310 in FIG. 32 scans the surface of the chip connecting portion 52 in one direction, the light source 310 may scan the surface of the chip connecting portion 52 in a plurality of directions. The light source 310 may be an apparatus that can simultaneously irradiate a plurality of laser beams 312.

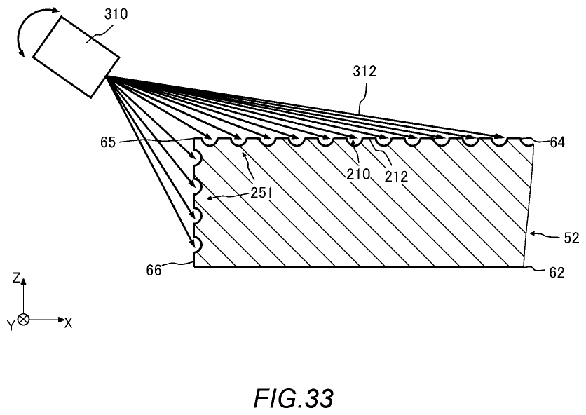

FIG. 33 is a diagram illustrating another example of laser irradiation in Step S341 of FIG. 29. The light source 310 irradiates at least two surfaces of the chip connecting portion 52 with a laser beam using a common light source 310 without replacing the chip connecting portion 52. In the present example, each surface of the chip connecting portion 52 is irradiated with the laser beam 312 by changing the irradiation angle without changing the arrangement of the laser light source. That is, the arrangement of the chip connecting portion 52 is fixed, and the light source 310 irradiates at least two surfaces of the chip connecting portion 52 with the plurality of laser beams 312 by changing the irradiation angle of the light source 310. The light source 310 may sequentially irradiate the surface of the chip connecting portion 52 with a plurality of laser beams 312. In this way, the plurality of concave portions 210 and the flat portion 212 disposed between the two concave portions 210 are formed in at least two surfaces of the chip connecting portion 52, and the inhibition region 251 can be provided in at least two surfaces of the chip connecting portion 52. In the present example, the plurality of concave portions 210 and the flat portion 212 disposed between the two concave portions 210 are formed in the surface of the edge surface 66 and the surface of the upper surface 64.

In the present example, the light source 310 obliquely irradiates each surface of the chip connecting portion with the laser beam 312. In FIG. 33, the light source 310 obliquely irradiates the surface of the edge surface 66 and the surface of the upper surface 64 with all the laser beams 312. That is, the laser beam 312 is not irradiated perpendicularly to the surface of the edge surface 66 and the surface of the upper surface 64. By irradiating the laser beam 312 obliquely, at least two surfaces of the chip connecting portion 52 can be irradiated with the laser beam 312 using the common light source 310 without replacing the chip connecting portion 52.

The light source 310 may irradiate each surface of the chip connecting portion 52 with a plurality of laser beams 312 without changing the focal position. Irradiating the plurality of laser beams 312 without changing the focal position allows the plurality of laser beams 312 to be continuously irradiated, and the processing time to be shortened. The focal position is aligned to, for example, a corner 65. The corner 65 is a portion where two surfaces of the chip connecting portion 52 intersect. In the example of FIG. 33, a portion where the upper surface 64 and the edge surface 66 intersect is defined as the corner 65. The focal position may be aligned to any position of the edge surface 66. The focal position may be aligned to any position of the upper surface 64. When a point close to the focal position is irradiated with the laser beam, the depth of the concave portion 210 increases. The focal position may be aligned to the corner 65. Forming the concave portion 210 deep in the vicinity of the corner 65 can suppress peeling between the chip connecting portion 52 and the resin 12 in the vicinity of the corner 65 where stress is likely to concentrate. The focal position may be aligned to the edge surface 66. Providing the concave portion 210 formed in the edge surface 66 deep can suppress the solder from crawling up in the edge surface 66.

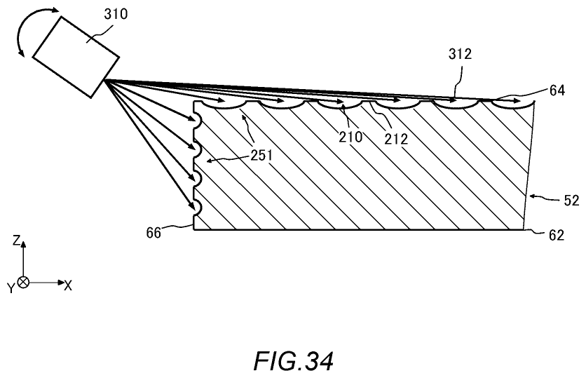

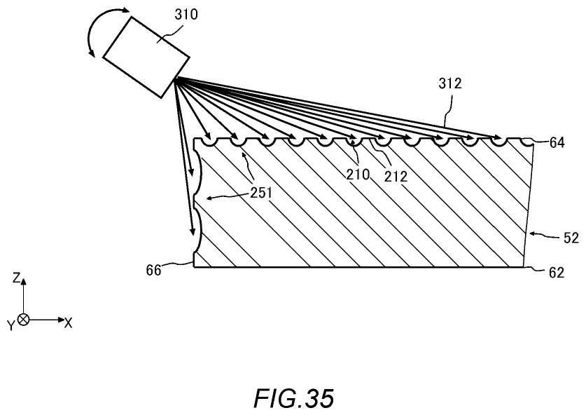

FIG. 34 and FIG. 35 are diagrams illustrating other examples of the laser irradiation in Step S341 of FIG. 29. In FIG. 34 and FIG. 35, the position of the light source 310 is different from that in FIG. 33. In FIG. 34, the light source 310 is provided on the edge surface 66 side as compared with FIG. 33. In FIG. 35, the light source 310 is provided on the upper surface 64 side as compared with FIG. 33.

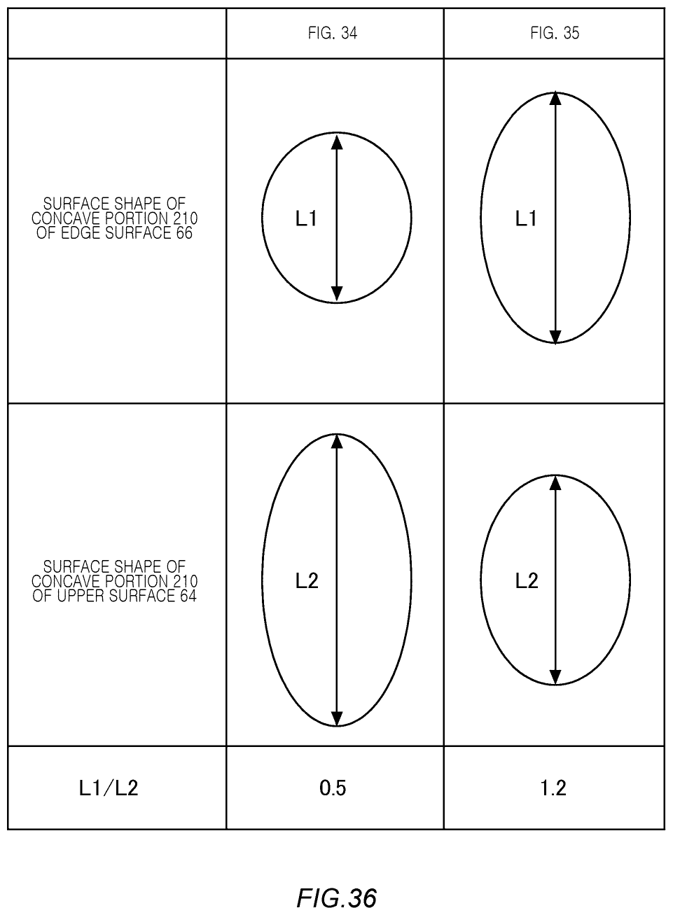

FIG. 36 is a diagram illustrating an example of the surface shapes of the concave portions 210 of the edge surface 66 and the upper surface 64. FIG. 36 illustrates an example of the surface shapes of the concave portion 210 in FIG. 34 and FIG. 35. In FIG. 36, the length in the longitudinal direction (Z axis direction in FIG. 34 and FIG. 35) of the surface shape of the concave portion 210 of the edge surface 66 is referred to as L1, and the length in the longitudinal direction (X axis direction in FIG. 34 and FIG. 35) of the surface shape of the concave portion 210 of the upper surface 64 is referred to as L2.

In FIG. 34, the light source 310 is provided on the edge surface 66 side as compared with FIG. 33. Therefore, an angle formed by the upper surface 64 and the laser beam 312 incident on the upper surface 64 is small as compared with that in FIG. 33. Therefore, the length L2 in the longitudinal direction of the surface shape of the concave portion 210 of the upper surface 64 is larger than the length L1 in the longitudinal direction of the surface shape of the concave portion 210 of the edge surface 66. In the present example, L1/L2 is 0.5.

In FIG. 35, the light source 310 is provided on the upper surface 64 side as compared with FIG. 33. Therefore, the angle formed by the edge surface 66 and the laser beam 312 incident on the edge surface 66 is small as compared with that in FIG. 33. Therefore, the length L1 of the surface shape of the concave portion 210 of the edge surface 66 in the longitudinal direction is larger than the length L2 of the surface shape of the concave portion 210 of the upper surface 64 in the longitudinal direction. In the present example, L1/L2 is 1.2.

Changing the relative position between the light source 310 and the chip connecting portion 52 allows the change of the surface shapes of the concave portions 210 of the edge surface 66 and the upper surface 64. L1/L2 may be 0.5 or more. L1/L2 may be 1.2 or less.

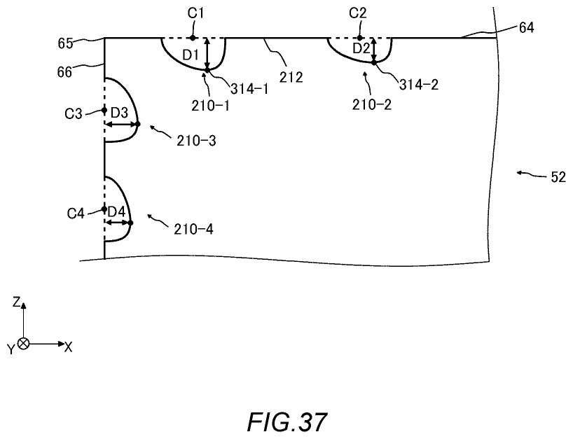

FIG. 37 is a diagram for explaining the shapes of the concave portions 210 of the edge surface 66 and the upper surface 64. In FIG. 37, the concave portion 210-1 and the concave portion 210-2 are provided in the upper surface 64. The concave portion 210-1 is provided closer to the edge surface 66 than the concave portion 210-2. The center of the concave portion 210-1 in the X axis direction is referred to as C1, and the center of the concave portion 210-1 in the X axis direction is referred to as C2. In FIG. 37, a concave portion 210-3 and a concave portion 210-4 are provided in the edge surface 66. The concave portion 210-3 is provided closer to the upper surface 64 than the concave portion 210-4. The center of the concave portion 210-3 in the Z axis direction is referred to as C3, and the center of the concave portion 210-4 in the Z axis direction is referred to as C4.

In the present example, each surface of the chip connecting portion 52 is obliquely irradiated with the laser beam 312. Therefore, the position of a bottom portion 314 of the concave portion 210 is shifted from the center of the concave portion 210. In the present example, the bottom portion 314 of at least one concave portion 210 formed in the upper surface 64 is disposed on the opposite side to the edge surface 66 of the chip connecting portion 52 with respect to the center of the concave portion 210. That is, a bottom portion 314-1 of the concave portion 210-1 is disposed on the opposite side to the edge surface 66 from the center C1 of the concave portion 210-1. A bottom portion 314-2 of the concave portion 210-2 is disposed on the opposite side to the edge surface 66 from the center C2 of the concave portion 210-2.

The bottom portion 314 of the at least one concave portion 210 formed in the edge surface 66 may be disposed on the opposite side to the upper surface 64 of the chip connecting portion with respect to the center of the concave portion 210. That is, a bottom portion 314-3 of the concave portion 210-3 may be disposed on the opposite side to the upper surface 64 from the center C3 of the concave portion 210-3. A bottom portion 314-4 of the concave portion 210-4 may be disposed on the opposite side to the upper surface 64 from the center C4 of the concave portion 210-4. The bottom portion 314 of the at least one concave portion 210 formed in the edge surface 66 may be disposed substantially coinciding with the center of the concave portion 210.

When the focal position is aligned to the corner 65, the depth of the concave portion 210 becomes shallower with increasing distance from the corner 65. Therefore, the depth of the concave portion 210 formed in the upper surface 64 becomes shallower with increasing distance from the edge surface 66. The depth of the concave portion 210 is the depth at the bottom portion 314. In the present example, a depth D2 of the concave portion 210-2 is smaller than a depth D1 of the concave portion 210-1. The depth of the concave portion 210 formed in the edge surface 66 becomes shallower with increasing distance from the upper surface 64. That is, a depth D4 of the concave portion 210-4 is smaller than a depth D3 of the concave portion 210-3.

The concave portion 210 formed in FIG. 33, FIG. 34, and FIG. 35 is the same in each of the upper surface 64 and the edge surface 66, but the concave portion 210 formed in FIG. 33, FIG. 34, and FIG. 35 may also have the shape of the concave portion 210 of FIG. 37. That is, in FIG. 33, FIG. 34, and FIG. 35, the bottom portion 314 of at least one concave portion 210 formed in the upper surface 64 may be disposed on the opposite side to the edge surface 66 of the chip connecting portion 52 with respect to the center of the concave portion 210. In FIG. 33, FIG. 34, and FIG. 35, the bottom portion 314 of at least one concave portion 210 formed in the edge surface 66 may be disposed on the opposite side to the upper surface 64 of the chip connecting portion with respect to the center of the concave portion 210. In FIG. 33, FIG. 34, and FIG. 35, the depth of the concave portion 210 formed in the upper surface 64 may become shallower with increasing distance from the edge surface 66. In FIG. 33, FIG. 34, and FIG. 35, only the concave portion 210 formed in the edge surface 66 may have the shape of the concave portion 210 in FIG. 37.

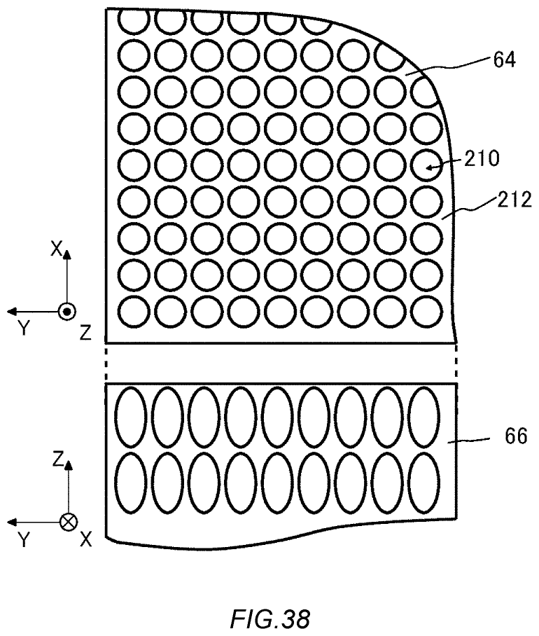

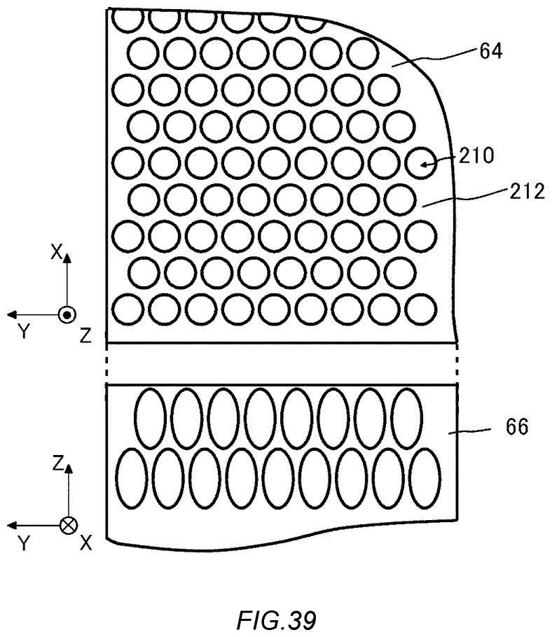

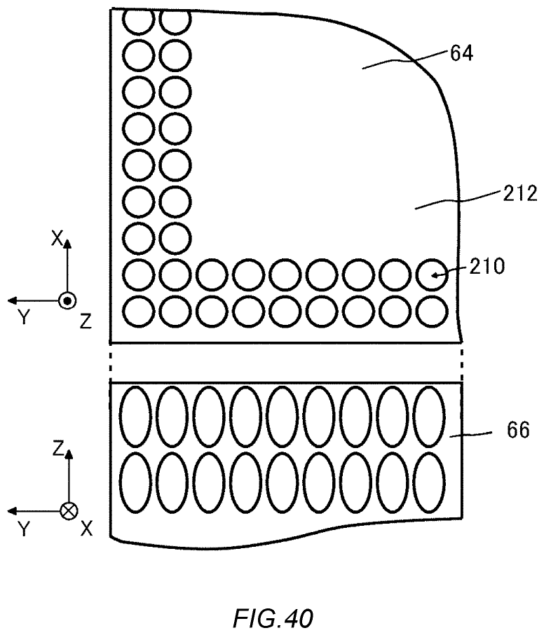

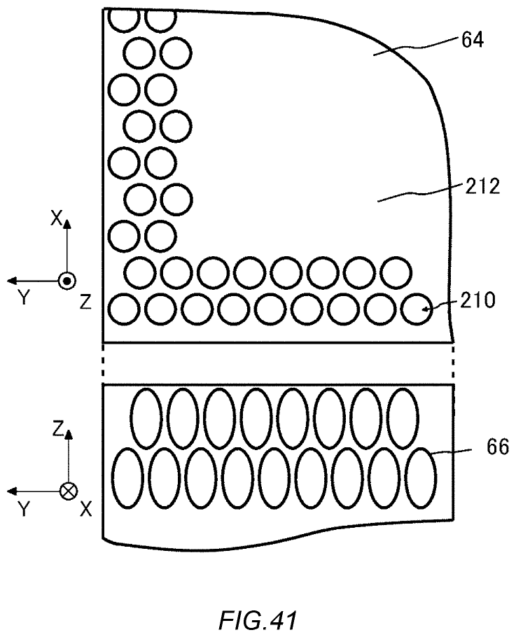

FIG. 38, FIG. 39, FIG. 40, and FIG. 41 are diagrams illustrating examples of the arrangement of the concave portions 210 of the upper surface 64 and the edge surface 66. In each drawing, the Y axis direction of the upper surface 64 and the edge surface 66 is illustrated in common. The concave portion 210 may be disposed on a straight line as illustrated in FIG. 38. As illustrated in FIG. 39, the concave portion 210 may be disposed in a lattice pattern. As illustrated in FIG. 40 and FIG. 41, the concave portion 210 may not be disposed in the entire upper surface 64. In FIG. 40 and FIG. 41, the concave portion 210 is disposed only in the vicinity of the edge surface 66 and the side surface 68 in the upper surface 64. Although FIG. 38, FIG. 39, FIG. 40, and FIG. 41 illustrate the arrangement of the concave portions 210 of the upper surface 64 and the edge surface 66, the concave portions 210 may be disposed in the lower surface 62 and the edge surface 66.

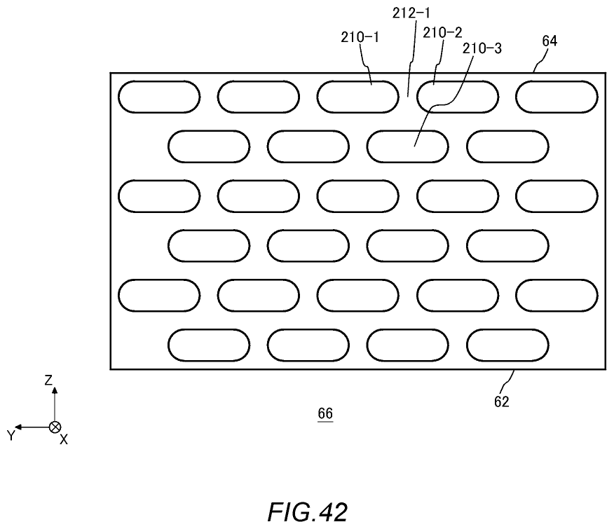

FIG. 42 is a diagram illustrating another arrangement example of the concave portions 210 and the flat portion 212 in the edge surface 66. The edge surface 66 of the present example is different from the example of FIG. 27 or 28 in the shape of the concave portion 210. The other structures are similar to the example of FIG. 27 or FIG. 28.

The width of the concave portion 210 in the lateral direction (Y axis direction) of the present example is larger than the width in the height direction (Z axis direction). According to the present example, the path from the lower surface 62 to the upper surface 64 through the flat portion 212 can be lengthened. Therefore, the crawling-up of the solder can be further suppressed. The concave portion 210 may have a shape such as an oval, an ellipse, or a rectangle in the edge surface 66. The width of the concave portion 210 in the lateral direction may be 1.5 times or more, 2 times or more, or 3 times or more of the width in the height direction. Note that the plurality of concave portions 210 is provided in the lateral direction. That is, the width of the concave portion 210 in the lateral direction is smaller than half of the width of the edge surface 66 in the lateral direction.

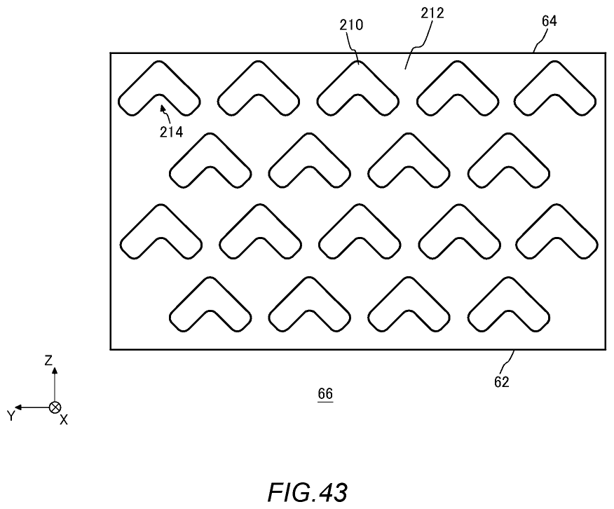

FIG. 43 is a diagram illustrating another arrangement example of the concave portions 210 and the flat portion 212 in the edge surface 66. The edge surface 66 of the present example is different from the example of FIG. 27, FIG. 28, or FIG. 42 in the shape of the concave portion 210. The other structures are similar to the example of FIG. 27, FIG. 28, or FIG. 42.

In the present example, the shape of the concave portion 210 in the edge surface 66 has a recessed portion 214. The recessed portion 214 is a portion where an end side of the concave portion 210 on the lower surface 62 side is recessed on the upper surface 64 side. The flat portion 212 in contact with the recessed portion 214 is surrounded by the concave portion 210 in three directions of the upper side and both sides in the lateral direction. Therefore, it is possible to suppress the solder that has reached the recessed portion 214 from further crawling up toward the upper surface 64 side.

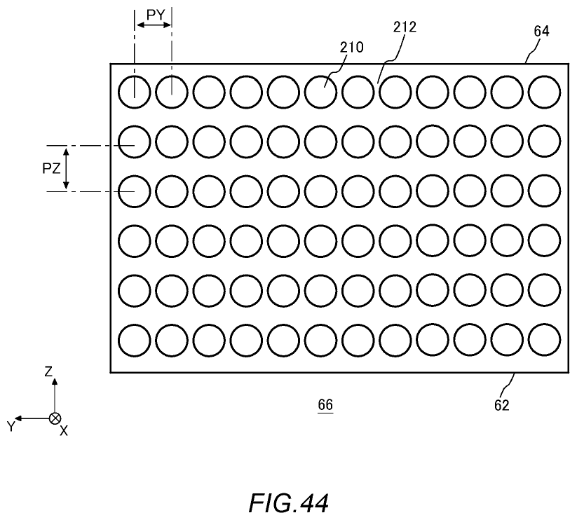

FIG. 44 is a diagram illustrating another arrangement example of the concave portions 210 and the flat portion 212 in the edge surface 66. The edge surface 66 of the present example is different from the example of FIG. 27, FIG. 28, FIG. 42, or FIG. 43 in the arrangement of the concave portions 210. The other structures are similar to the example of FIG. 27, FIG. 28, FIG. 42, or FIG. 43.

In the present example, the density of the plurality of concave portions 210 in the lateral direction (Y axis direction) is higher than the density of the plurality of concave portions 210 in the height direction (Z axis direction). The density of the concave portions 210 may be the reciprocal of the interval of two concave portions 210 adjacent to each other in each direction. The interval of the concave portions 210 is the interval P described in FIG. 26. In the example of FIG. 42, an interval PY of the concave portions 210 in the lateral direction is smaller than an interval PZ of the concave portions 210 in the height direction. The interval PZ may be 1.5 times or more, or 2 times or more of the interval PY. According to the present example, since the interval PY of the concave portions 210 in the lateral direction is small, it is possible to suppress the solder from passing between the two concave portions 210 arranged in the lateral direction.

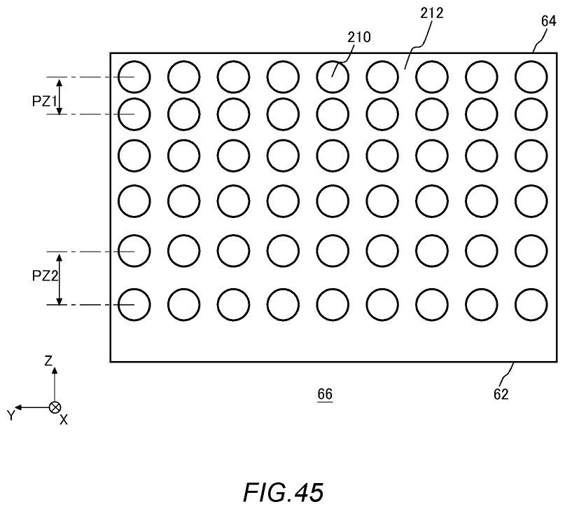

FIG. 45 is a diagram illustrating another arrangement example of the concave portions 210 and the flat portion 212 in the edge surface 66. The edge surface 66 of the present example is different from the example of FIG. 27, FIG. 28, or FIG. 42 to FIG. 44 in the arrangement of the concave portions 210. The other structures are similar to any of the examples of FIG. 27, FIG. 28, or FIG. 42 to FIG. 44.

In the present example, the density of the plurality of concave portions 210 in the height direction (Z axis direction) is higher with increasing distance from the lower surface 62. As an example, among the intervals PZ of pairs of concave portions 210 adjacent in the height direction, the interval of the pair closest to the upper surface 64 is referred to as PZ1, and the interval of the pair closest to the lower surface 62 is referred to as PZ2. The interval PZ2 is larger than the interval PZ1. The interval PZ2 may be 1.5 times or more, or may be 2 times or more of the interval PZ1. According to the present example, since the interval PZ of the concave portions 210 in the vicinity of the upper surface 64 is small, the crawling-up of the solder can be suppressed with decreasing distance to the upper surface 64.

In the examples of FIG. 31 to FIG. 45 described above, the edge surface 66 has been described as an example. However, similarly to the edge surface 66, the inhibition region 251 may also be provided on each side surface 68 as in Step S341. That is, the inhibition region 251 may be configured by forming the plurality of concave portions 210 and the flat portion 212 in the edge surface 66, each side surface 68, and the upper surface 64. In addition, the lead frame 50 described in the examples of FIG. 31 to FIG. 45 may also have the rough surface region 51 described in FIG. 1 to FIG. 23. The inhibition region 251 may function as the rough surface region 51.

Method of Manufacturing Rough Surface Region 51 and Inhibition Region 251; Description of Die Roughening

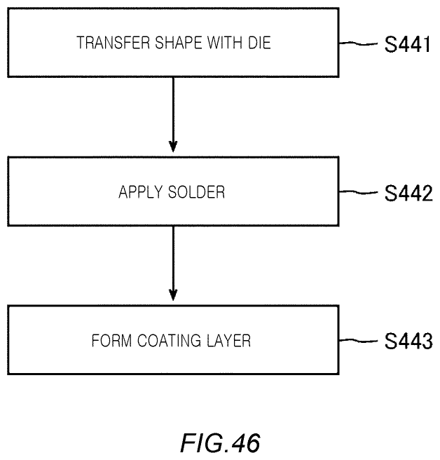

FIG. 46 is a diagram illustrating some steps in the method of manufacturing the semiconductor module 100. In the present example, the shape is transferred to the surface of the chip connecting portion 52, specifically, the upper surface 64 of the chip connecting portion 52 by a die, and the inhibition region 251 in which the plurality of concave portions 210 and the flat portion 212 are formed is provided (S441).

Next, the lead frame 50 is soldered to the semiconductor chip 40 by the solder 32 (S442). Since the concave portions 210 and the flat portion 212 are formed in the edge surface 66 and the like before Step S442, it is possible to suppress the solder 32 from crawling up in the edge surface 66 and the like. Step S442 may be the same step as Step S342 in FIG. 29.

Next, the coating layer 13 is formed (S443). In Step S443, the coating layer 13 may be formed in the surfaces of the lead frame 50 and the solder 32. After Step S443, the lead frame 50, the semiconductor chip 40, and the like may be sealed with the resin 12. This can consequently form the semiconductor module 100. Step S443 may be the same step as Step S343 in FIG. 29.

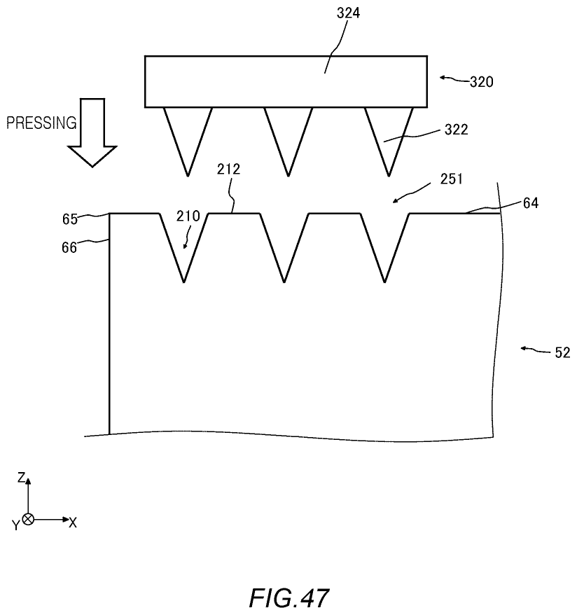

FIG. 47 is a diagram for explaining shape transfer to the chip connecting portion 52 by a die 320. In the present example, the die 320 transfers the shape to the surface of the chip connecting portion 52. The concave portions 210 and the flat portion 212 can be formed by transferring the shape to the surface of the chip connecting portion 52. In the present example, the shape is transferred to the upper surface 64 to form the three concave portions 210 and the flat portion 212. That is, in the present example, the three concave portions 210 are die holes formed by pressing. In the pressing for forming the three concave portions 210, the lower surface 62 which is a surface opposite to the upper surface 64 may not be pushed out. That is, the shape of the lower surface 62 of the chip connecting portion 52 does not change and may remain flat before and after the formation of the die hole. On the other hand, when the protrusion 88 is formed by pressing, the upper surface 64 may be dented, and the convex portion that becomes the protrusion 88 may be formed by pushing out the lower surface 62 by the dented amount of the upper surface 64.

The die 320 includes a first portion 322 and a second portion 324. The die 320 can transfer the shape of the first portion 322. As an example, the first portion 322 has a quadrangular pyramid shape. The first portion 322 preferably has a shape in which the first portion 322 can be easily pulled out after the shape is transferred. The second portion 324 is connected to the three first portions 322.

In the present example, the concave portion 210 and the flat portion 212 are formed by pressing with the die 320 and compressing the chip connecting portion 52. Thus, the concave portion 210 is compressed as compared to other surfaces. The concave portion 210 may be compressed more than the flat portion 212. The fact that the concave portion 210 is compressed may mean that the hardness of the concave portion 210 is higher than that of other surfaces. The fact that the concave portion 210 is compressed may mean that the density of the concave portions 210 is higher than that of other surfaces.

The surface of the chip connecting portion 52 may be a rough surface region having a developed interfacial area ratio of 0.1 or more. The surface of the chip connecting portion 52 may be a rough surface region having a developed interfacial area ratio of 0.4 or less, preferably 0.35 or less, and more preferably 0.3 or less. The concave portions 210 and the flat portion 212 are formed by the die 320, so that the surface of the chip connecting portion 52 can be a rough surface region.

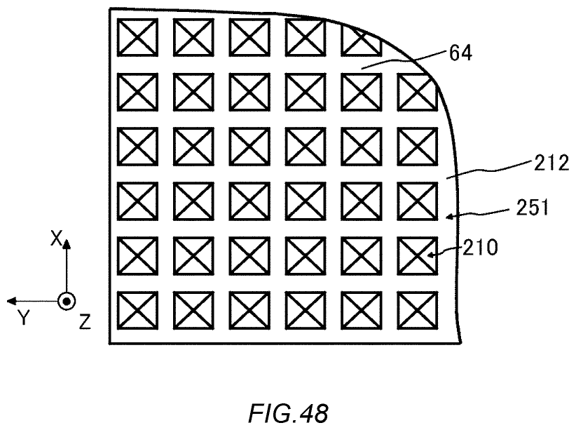

FIG. 48 is a diagram illustrating an example of the arrangement of the concave portions 210 and the flat portion 212 of the upper surface 64. The concave portions 210 may be disposed on a straight line as illustrated in FIG. 48. The shape of the upper surface of the concave portion 210 may be a polygonal shape. In the present example, the shape of the upper surface of the concave portion 210 is a quadrangular shape.

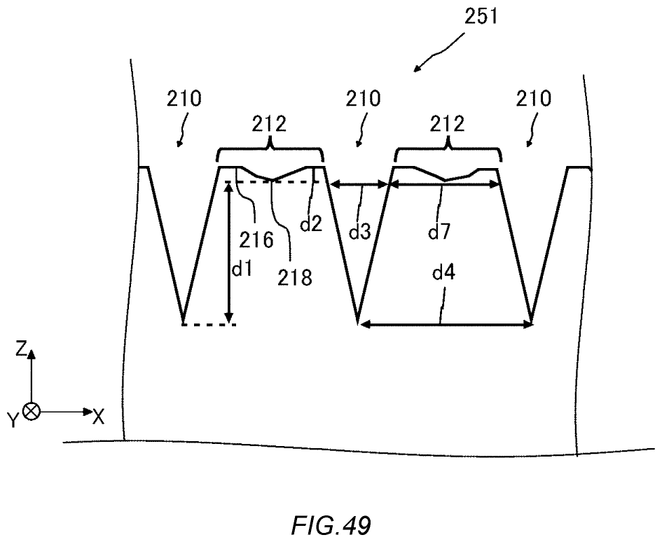

FIG. 49 is a diagram for explaining in detail the shapes of the concave portions 210 and the flat portion 212 of the upper surface 64. FIG. 49 illustrates the shapes of the concave portions 210 and the flat portion 212 formed by a die. In the present example, the flat portion 212 has a raised portion 216 and a standard portion 218. Forming the concave portion 210 by a die allows the raised portion 216 to be formed adjacent to the concave portion 210. The raised portion 216 has the same height in the height direction as the standard portion 218 or is a portion raised in the height direction from the standard portion 218. In the present example, the raised portion 216 is raised in the height direction from the standard portion 218. The standard portion 218 is a portion of which the height does not change from the surface before the concave portion 210 is formed, for example. The standard portion 218 is adjacent to the raised portion 216. The standard portion 218 may be recessed in the height direction from the raised portion 216. At least a part of the concave portion 210 is disposed to be recessed from the standard portion 218 in the height direction. The raised portion 216 is sandwiched between the concave portion 210 and the standard portion 218.

As a method of discriminating the raised portion 216, the standard portion 218, and the concave portion 210, the respective heights in the height direction may be compared and discriminated. A difference d1 between the standard portion 218 and the concave portion 210 in the height direction is larger than a difference d2 (which may be the depth of the concave portion 210) between the raised portion 216 and the standard portion 218 in the height direction. d2 may be 30% or less of d1. d2 may be 20% or less of d1. When d2 is smaller than d1, the raised portion 216, the standard portion 218, and the concave portion 210 can be discriminated. As another method of discriminating the raised portion 216, the standard portion 218, and the concave portion 210, a portion that looks like a plane when the upper surface 64 is observed (see, for example, FIG. 48) may be discriminated as the standard portion 218.

d1 may be 20 μm or more. d1 may be 200 μm or less. d1 may be more preferably 50 μm or more and 150 μm or less. A width d3 of the concave portion 210 may be 50 μm or more. d3 may be 250 μm or less. d3 is more preferably 100 μm or more and 200 μm or less. A pitch width d4 of the concave portion 210 may be 200 μm or more. d4 may be 700 μm or less. d4 is more preferably 300 μm or more and 600 μm or less. A minimum length d7 of the flat portion 212 may be 150 μm or more. d7 may be 450 μm or less. d7 is more preferably 200 μm or more and 400 μm or less. The minimum length d7 may be a length obtained by extending the standard portion 218 in the horizontal direction (X axis direction or Y axis direction). In FIG. 49, the minimum length d7 of the flat portion 212 is the minimum length between the concave portions 210 when the standard portion 218 is extended in the horizontal direction (X axis direction or Y axis direction). However, the minimum length d7 may be approximated to the minimum length of a portion where the concave portion 210 is not formed in a plan view.

In the present example, the shapes of the concave portions 210 and the flat portion 212 formed by a die are illustrated, but the concave portions 210 and the flat portion 212 formed by laser irradiation may also have the similar shape. That is, the flat portion 212 formed by laser irradiation may have the raised portion 216 and the standard portion 218. In the case of being formed by laser irradiation, d1 is, for example, 10 μm.

In the above-described examples of FIG. 46 to FIG. 49, as in Step S441, the inhibition region 251 may be configured by forming the plurality of concave portions 210 and the flat portion 212 in the edge surface 66, each side surface 68, and the upper surface 64, or the inhibition region 251 may be configured only in the upper surface 64. Note that the lead frame 50 described in the examples of FIG. 46 to FIG. 49 may also have the rough surface region 51 described in FIG. 1 to FIG. 23. The inhibition region 251 may function as the rough surface region 51.

Method of Manufacturing Rough Surface Region 51 and Inhibition Region 251; Description of Liquid Roughening

Although the method of forming the rough surface region 51 by laser irradiation and a die has been described, the rough surface region 51 may be formed using a roughening liquid. The roughening liquid may be commercially available. When the roughening liquid is used, a mask may be used for the surface on which the rough surface region 51 is not formed, or the entire surface may be roughened without using a mask.

Combination of Roughening Methods (Laser Roughening, Die Roughening, Liquid Roughening)

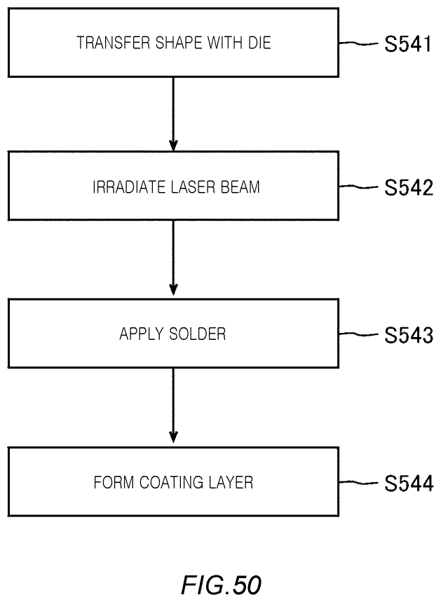

FIG. 50 is a diagram illustrating some steps in the method of manufacturing the semiconductor module 100. In the present example, the shape is transferred to the surface of the chip connecting portion 52, specifically, the upper surface 64 of the chip connecting portion 52 by a die to form the plurality of concave portions 210 and the flat portion 212 (S541). Step S541 may be the same step as Step S441 in FIG. 46.

After the shape is transferred by a die (S541), the surface of the chip connecting portion 52, specifically, at least the edge surface 66 is irradiated with a laser beam to form the plurality of concave portions 210 and the flat portion 212, and the inhibition region 251 is provided (S542). In Step S542, the plurality of concave portions 210 and the flat portion 212 may also be formed on each of the side surfaces 68 and the upper surface 64.

Next, the lead frame 50 is soldered to the semiconductor chip 40 by the solder 32 (S543). Since the concave portions 210 and the flat portion 212 are formed in the edge surface 66 and the like before Step S543, it is possible to suppress the solder 32 from crawling up in the edge surface 66 and the like. Step S543 may be the same step as Step S342 in FIG. 29.

Next, the coating layer 13 is formed (S544). In Step S544, the coating layer 13 may be formed in the surfaces of the lead frame 50 and the solder 32. After Step S544, the lead frame 50, the semiconductor chip 40, and the like may be sealed with the resin 12. This can consequently form the semiconductor module 100. Step S544 may be the same step as Step S343 in FIG. 29.

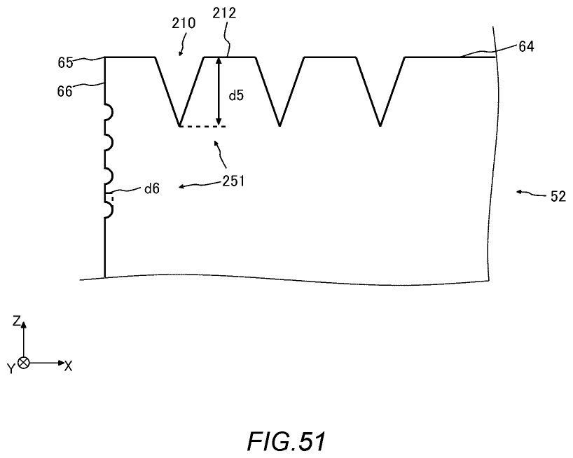

FIG. 51 is a diagram for explaining the shape of the chip connecting portion 52. In the present example, the shape is transferred to the upper surface 64 of the chip connecting portion 52 by a die. After the shape is transferred by a die, the edge surface 66 of the chip connecting portion 52 is irradiated with a laser beam. Therefore, the concave portion 210 formed in the upper surface 64 is a die hole. The concave portion 210 formed in the edge surface 66 is a laser hole.

The depth of the die hole is deeper than the depth of the laser hole. That is, a depth d5 of the concave portion 210 formed in the upper surface 64 is deeper than a depth d6 of the concave portion 210 formed in the edge surface 66. Such a configuration can be achieved by providing the die hole in the upper surface 64 and providing the laser hole in the edge surface 66.

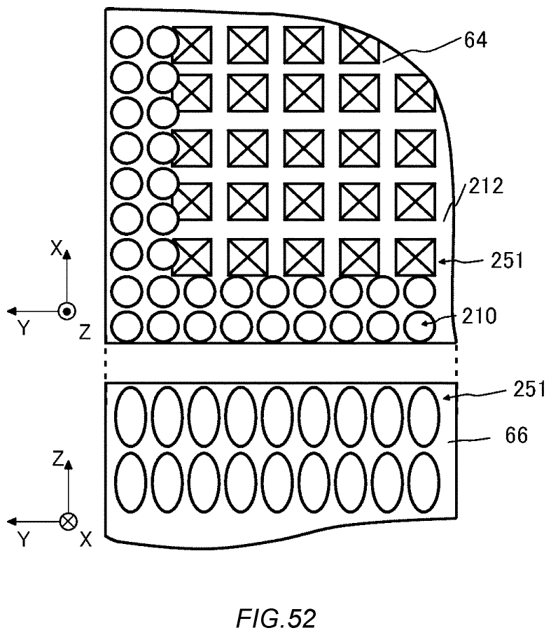

FIG. 52 is a diagram illustrating an example of the arrangement of the concave portions 210 and the flat portion 212 of the upper surface 64 and the edge surface 66. In FIG. 52, the Y axis direction of the upper surface 64 and the edge surface 66 is illustrated in common. The concave portion 210 is formed by obliquely irradiating the edge surface 66 and the upper surface 64 of the chip connecting portion 52 with the laser beam 312. In the upper surface 64, the concave portion 210 formed by laser irradiation is disposed only in the vicinity of the edge surface 66 and the side surface 68. The concave portion 210 formed by a die is disposed in the upper surface 64. The concave portion 210 formed by laser irradiation has a curved line. In the present example, the concave portion 210 formed by laser irradiation has a circular shape. The shape in the edge surface 66 of the concave portion 210 has a curved line. The concave portion 210 formed by a die has a polygonal shape. In the present example, the concave portion 210 formed by a die has a quadrangular shape.

In the present example, laser irradiation is performed so as to overlap at least some of the plurality of concave portions 210 to which the shape has been transferred by a die. That is, the concave portion 210 formed by laser irradiation and the concave portion 210 formed by a die at least partially overlap in the upper surface. Such a configuration allows the inhibition region 251 to be provided in the entire upper surface 64.

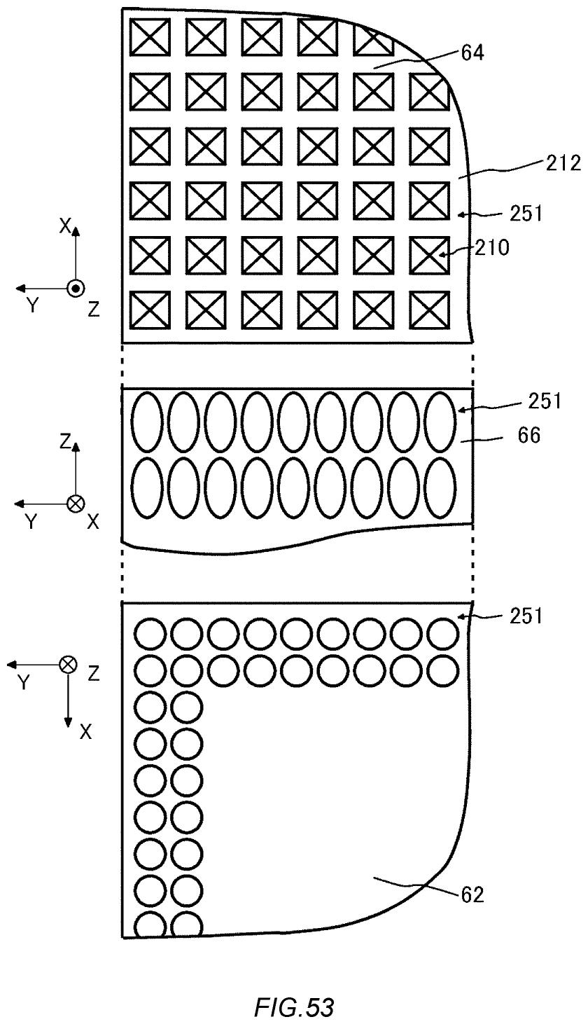

FIG. 53 is a diagram illustrating an example of the arrangement of the concave portions 210 of the upper surface 64, the edge surface 66, and the lower surface 62. In FIG. 53, the Y axis direction of the upper surface 64, the edge surface 66, and the lower surface 62 is illustrated in common. The concave portion 210 is formed by obliquely irradiating the edge surface 66 and the lower surface 62 of the chip connecting portion 52 with the laser beam 312. The concave portion 210 formed by a die is disposed in the upper surface 64. Such an arrangement allows the inhibition region 251 to be provided in the upper surface 64, the edge surface 66, and the lower surface 62. Note that each side surface 68 may form the inhibition region 251 similarly to the edge surface 66.

In the above-described examples of FIG. 50 to FIG. 53, as in Steps S541 and S542, the inhibition region 251 may be configured by forming the plurality of concave portions 210 and the flat portion 212 in the edge surface 66, each side surface 68, and the upper surface 64, or the inhibition region 251 may be configured only in the upper surface 64. Note that the lead frame 50 described in the examples of FIG. 50 to FIG. 53 may also have the rough surface region 51 described in FIG. 1 to FIG. 23. The inhibition region 251 may function as the rough surface region 51. In this case, the region of the upper surface 64 where the die hole is formed may have a developed interfacial area ratio of 0.1 or more. The developed interfacial area ratio of the regions of the edge surface 66 and the side surfaces 68 where the laser holes are formed may be 0.2 or more.

In the above description, an example in which laser roughening and die roughening are used in combination has been described, but the present embodiment is not limited thereto. For example, laser roughening and liquid roughening may be used in combination, or die roughening and liquid roughening may be used in combination.

Description of Another Example of Arrangement of Inhibition Region 251

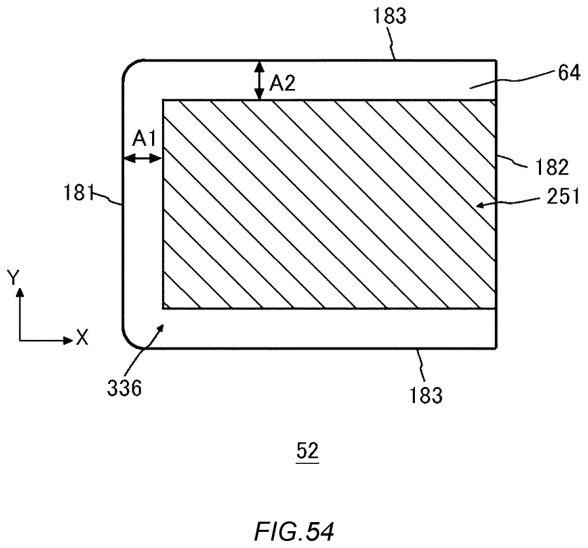

FIG. 54 is a diagram illustrating another example of the arrangement of the inhibition region 251. FIG. 54 illustrates an example of the arrangement of the inhibition regions 251 in the upper surface 64 of the chip connecting portion 52. In FIG. 54, the inhibition region 251 is indicated by hatching. In another example of the arrangement of the inhibition region 251, the plurality of concave portions 210 is periodically disposed in at least two directions of at least any one surface of the chip connecting portion 52. Any one surface of the chip connecting portion 52 has an unprocessed portion 336 in which the periodic arrangement is interrupted. The unprocessed portion 336 may be the flat portion 212.

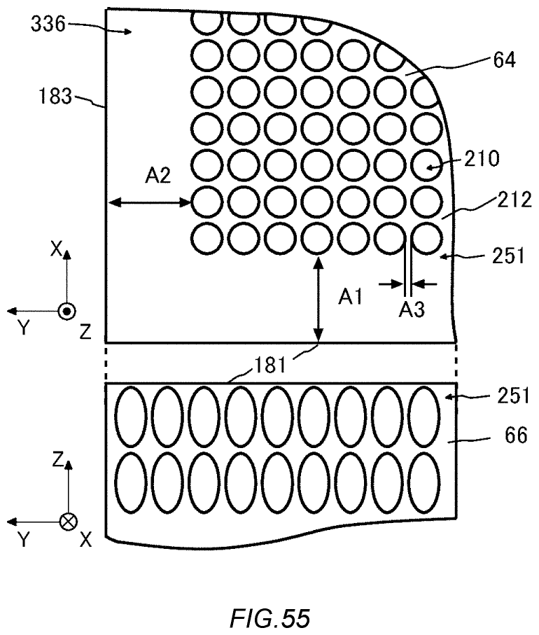

FIG. 55 is a diagram illustrating an example of the arrangement of the concave portions 210 of the upper surface 64 and the edge surface 66 in FIG. 54. FIG. 55 illustrates the arrangement of the plurality of concave portions 210 and the flat portion 212. The inhibition region 251 may be formed by forming the plurality of concave portions 210 and the flat portion 212. The inhibition region 251 may function as the rough surface region 51. That is, the inhibition region 251 may have any structure and function described as the rough surface region 51 in addition to the structure and function described as the inhibition region 251.

As illustrated in FIG. 54 and FIG. 55, the plurality of concave portions 210 and the flat portion 212 are formed in the upper surface 64 of the chip connecting portion 52. As illustrated in FIG. 55, the plurality of concave portions 210 and the flat portion 212 are formed in the edge surface 66 of the chip connecting portion 52. Although not illustrated, the plurality of concave portions 210 and the flat portion 212 may be formed in the side surface 68 of the chip connecting portion 52 similarly to the edge surface 66.

Among the end sides constituting the outer shape of the upper surface 64, the end side farthest from the bridge portion 54 is defined as an end side 181. In the present example, the upper surface 64 has a substantially rectangular shape having two sets of two sides parallel to each other, but may have another shape. The end side of the upper surface 64 may be a straight line. The end side 181 is connected to the edge surface 66. That is, the upper surface 64 and the edge surface 66 are connected at the end side 181. Among the end sides of the upper surface 64, the end side closest to the bridge portion 54 is defined as an end side 182. The end side 182 is connected to the side surface 68. That is, the upper surface 64 and the side surface 68 are connected at the end side 182. Among the end sides of the upper surface 64, the side between the end side 181 and the end side 182 is defined as an end side 183. The end side 183 is connected to the side surface 68. That is, the upper surface 64 and the side surface 68 are connected at the end side 183. The end side 181 and the end side 183 may be connected in a curved line in a top view.

In the present example, the plurality of concave portions 210 and the flat portion 212 are formed by laser roughening. The plurality of concave portions 210 and the flat portion 212 may be formed by die roughening. The plurality of concave portions 210 and the flat portion 212 may be formed by liquid roughening.

In the present example, the inhibition region 251 is not provided in the vicinity of the end side 181 and the end side 183. That is, the unprocessed portion 336 may be provided in the vicinity of an end side 181 and an end side 183. In FIG. 55, a shortest distance A1 between the concave portion 210 and the end side 181 is larger than an interval A3 of the adjacent concave portions 210. The interval A3 of the adjacent concave portions 210 may be the minimum length of the flat portion 212 (d7 in the example of FIG. 49). The shortest distance A1 may be 2 times or more, 5 times or more, or 10 times or more of the interval A3. In FIG. 55, a shortest distance A2 between the concave portion 210 and the end side 183 is larger than the interval A3 of the adjacent concave portions 210. The shortest distance between the concave portion 210 formed in the upper surface 64 and at least one end side of the surface (upper surface 64) may be larger than the interval A3 of the adjacent concave portions 210. The shortest distance A2 may be 5 times or more, 10 times or more, or 20 times or more of the interval A3.

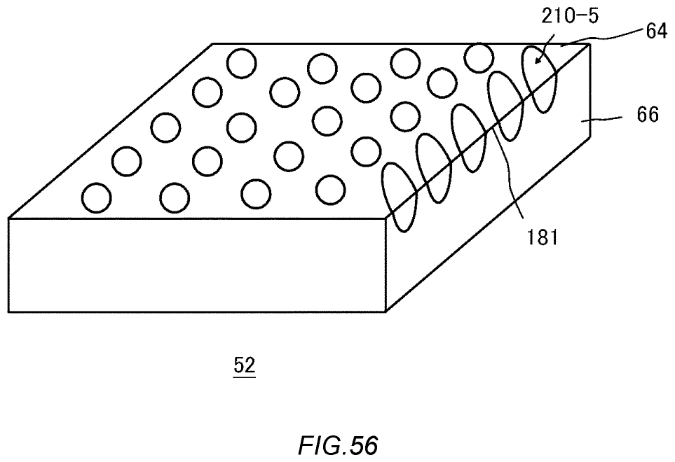

FIG. 56 is a diagram illustrating an example of the chip connecting portion 52 according to a comparative example. If the inhibition region 251 is provided in the vicinity of the end side (the end side 181 in the example of FIG. 56) of the upper surface 64, one concave portion 210-5 may be formed on both the upper surface 64 and the edge surface 66 (or the side surface 68). When the concave portion 210-5 is provided, the solder is likely to wet and spread from the edge surface 66 (or the side surface 68) to the upper surface 64. In the examples of FIG. 54 and FIG. 55, since the inhibition region 251 is not provided in the vicinity of the end side 181 and the end side 183, it is possible to suppress generation of the concave portion 210-5 and to suppress wet-spreading of the solder. From the viewpoint of suppressing wet-spreading of the solder, the developed interfacial area ratio of the upper surface 64 on which the plurality of concave portions 210 is formed is preferably set to 0.7 or less.

The shortest distance A1 between the concave portion 210 and the end side 181 may be 0.3 mm or more and 1.5 mm or less. The shortest distance A2 between the end side 183 and the concave portion 210 may be 0.3 mm or more and 1.5 mm or less. The interval A3 of the adjacent concave portions 210 may be 30 μm or more and 60 μm or less.

The shortest distance A1 between the concave portion 210 and the end side 181 may be larger than the thickness of the chip connecting portion 52 in the Z axis direction. The shortest distance A2 between the concave portion 210 and the end side 183 may be larger than the thickness of the chip connecting portion 52 in the Z axis direction. The thickness of the chip connecting portion 52 in the Z axis direction may be 0.3 mm or more, and preferably 0.5 mm or more.

The shortest distance A1 between the concave portion 210 formed in the upper surface 64 of the chip connecting portion and the end side 181 may be larger than the shortest distance between the concave portion 210 formed in the edge surface 66 of the chip connecting portion 52 and the end side 181. As illustrated in FIG. 55, the concave portion 210 may be provided in the vicinity of the end side 181 in the edge surface 66 of the chip connecting portion 52. Similarly to the edge surface 66, the shortest distance A2 between the concave portion 210 formed in the upper surface 64 of the chip connecting portion and the end side 183 may be larger than the shortest distance (not illustrated) between the concave portion 210 formed in the side surface 68 of the chip connecting portion 52 and the end side 183. The concave portion 210 may not be provided in the vicinity of the end side 181 in the edge surface 66 of the chip connecting portion 52. That is, the shortest distance between the concave portion 210 formed in the edge surface 66 of the chip connecting portion 52 and the end side 181 may be larger than the interval A3 of the adjacent concave portions 210.

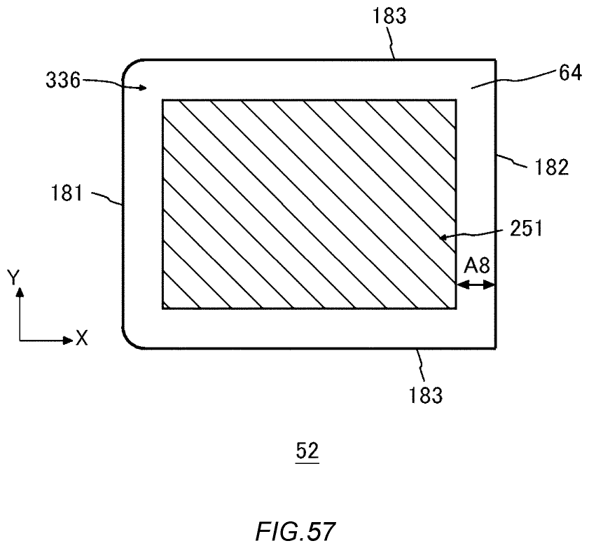

FIG. 57 is a diagram illustrating another example of the arrangement of the inhibition region 251. FIG. 57 is different from FIG. 54 in that the inhibition region 251 is not provided in the vicinity of the end side 182. That is, the unprocessed portion 336 may be provided in the vicinity of the end side 182. The other configurations in FIG. 57 may be the same as those in FIG. 54.

A shortest distance A8 between the concave portion 210 and the end side 182 may be larger than the interval A3 (see FIG. 55) of the adjacent concave portions 210. The shortest distance A8 between the concave portion 210 and the end side 182 may be 0.3 mm or more and 1.5 mm or less. Such a configuration can suppress wet-spreading of the solder in the vicinity of the bridge portion 54.

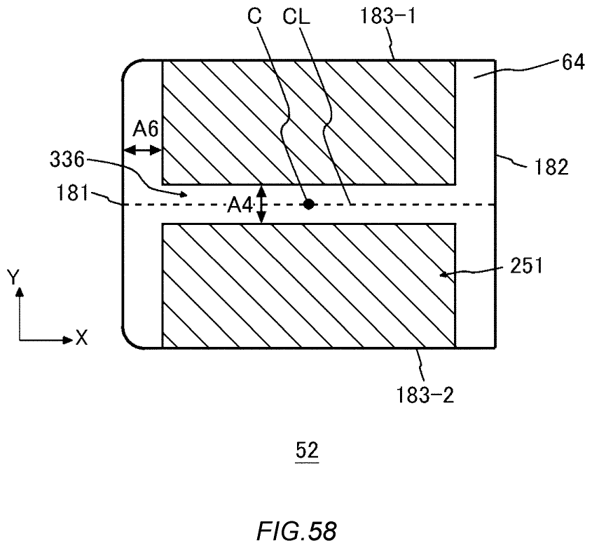

FIG. 58 is a diagram illustrating another example of the arrangement of the inhibition region 251. FIG. 58 illustrates an example of the arrangement of the inhibition regions 251 in the upper surface 64 of the chip connecting portion 52. In FIG. 58, the inhibition region 251 is indicated by hatching.

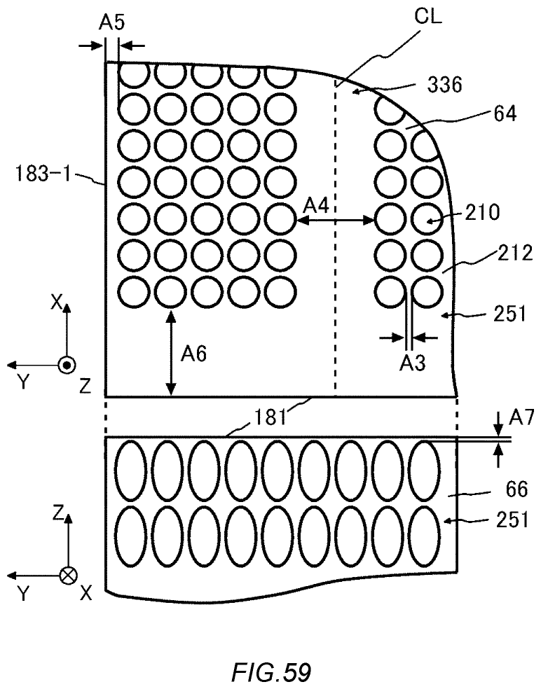

FIG. 59 is a diagram illustrating an example of the arrangement of the concave portions 210 of the upper surface 64 and the edge surface 66 in FIG. 58. FIG. 59 illustrates the arrangement of the plurality of concave portions 210 and the flat portion 212. The inhibition region 251 may be formed by forming the plurality of concave portions 210 and the flat portion 212. The inhibition region 251 may function as the rough surface region 51. In the present example, the plurality of concave portions 210 and the flat portion 212 are formed by laser roughening.

In the present example, an end side 183-1 is opposite to an end side 183-2. The end side 183-1 is an example of a first end side. The end side 183-2 is an example of a second end side. The end side 181 is an example of a third end side.

In the present example, the inhibition region 251 is not provided in the vicinity of a center line CL of the upper surface 64 of the chip connecting portion 52. That is, the unprocessed portion 336 may be provided in the vicinity of the center line CL. The center line CL is a line passing through the center C of the upper surface 64 of the chip connecting portion 52. The center line CL is parallel to the X axis direction. The center C of the upper surface 64 of the chip connecting portion 52 may be the center of the upper surface 64 of the chip connecting portion 52 in the XY plane or the center of gravity of the upper surface 64 of the chip connecting portion 52. A maximum distance A4 in the intervals of the concave portions 210 sandwiched between the end side 183-1 and the end side 183-2 is larger than a first shortest distance A5 (see FIG. 59) between the concave portion 210 formed in the upper surface 64 of the chip connecting portion 52 and the end side 183-1. The maximum distance A4 in the intervals of the concave portions 210 sandwiched between the end side 183-1 and the end side 183-2 is larger than the second shortest distance (not illustrated) between the concave portion 210 formed in the upper surface 64 of the chip connecting portion 52 and the end side 183-2.

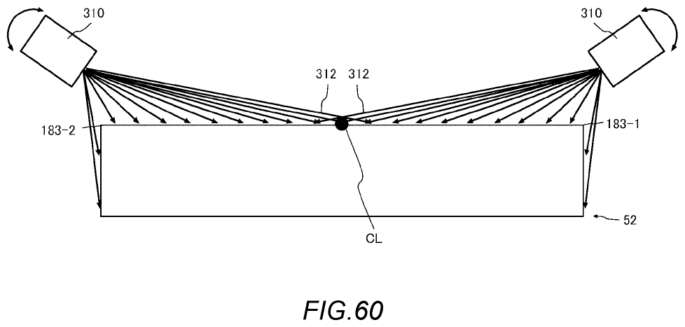

FIG. 60 is a diagram for explaining laser irradiation to the chip connecting portion 52 according to a comparative example. In a case where at least two surfaces of the chip connecting portion 52 are irradiated with a laser beam by the common light source 310 without replacing the chip connecting portion 52 as illustrated in FIG. 33, for example, a case where the laser beam 312 is obliquely irradiated toward the end side 183-1 and the end side 183-2 is considered. In this case, it is conceivable that spots of laser irradiation (irradiation positions of laser irradiation) overlap each other in the vicinity of the center line CL of the upper surface 64 of the chip connecting portion 52. In this case, the solder is likely to wet and spread in the vicinity of the center line CL of the upper surface 64 of the chip connecting portion 52. In the present example, since the inhibition region 251 is not provided in the vicinity of the center line CL of the upper surface 64 of the chip connecting portion 52, it is possible to prevent spots of laser irradiation from overlapping each other in the vicinity of the center line CL of the upper surface 64 of the chip connecting portion 52. Therefore, wet-spreading of the solder can be suppressed.

The maximum distance A4 in the intervals of the concave portions 210 sandwiched between the end side 183-1 and the end side 183-2 may be, for example, 0.3 mm or more and 1.5 mm or less. The first shortest distance A5 between the concave portion 210 formed in the upper surface 64 of the chip connecting portion 52 and the end side 183-1 may be 30 μm or more and 60 μm or less. The second shortest distance between the concave portion 210 formed in the upper surface 64 of the chip connecting portion 52 and the end side 183-2 may be 30 μm or more and 60 μm or less.

The interval of the concave portions 210 at the center C between the end side 183-1 and the end side 183-2 of the upper surface 64 of the chip connecting portion 52 may be larger than the first shortest distance A5 and the second shortest distance. Providing the interval of the concave portions 210 at the center larger than the first shortest distance A5 and the second shortest distance allows spots of laser irradiation to be prevented from overlapping each other in the vicinity of the center C. The maximum distance A4 in the intervals of the concave portions 210 sandwiched between the end side 183-1 and the end side 183-2 may be the interval of the concave portions 210 at the center C. That is, the interval of the concave portions 210 may be maximum at the center C between the end side 183-1 and the end side 183-2. The interval of the concave portions 210 may not be the maximum at the center C.

A shortest distance A6 between the concave portion 210 formed in the upper surface 64 of the chip connecting portion 52 and the end side 181 is larger than the first shortest distance A5. The shortest distance A6 between the concave portion 210 formed in the upper surface 64 of the chip connecting portion 52 and the end side 181 is larger than the second shortest distance. Therefore, since the inhibition region 251 is not provided in the vicinity of the end side 181, wet-spreading of the solder can be suppressed.

The shortest distance A6 between the concave portion 210 formed in the upper surface 64 of the chip connecting portion 52 and the end side 181 is larger than a shortest distance A7 between the concave portion 210 formed in the edge surface 66 of the chip connecting portion 52 and the end side 181. That is, in the edge surface 66, the inhibition region 251 is provided in the vicinity of the end side 181. Providing the inhibition region 251 in the vicinity of the end side 181 in the edge surface 66 suppresses the solder from wet-spreading. Note that the shortest distance A7 between the concave portion 210 formed in the edge surface 66 of the chip connecting portion 52 and the end side 181 may be larger than the interval A3 of the adjacent concave portions 210.

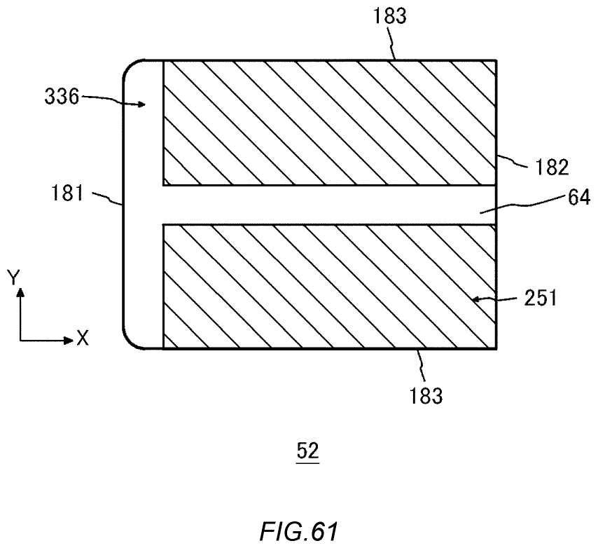

FIG. 61 is a diagram illustrating another example of the arrangement of the inhibition region 251. FIG. 61 is different from FIG. 58 in that the inhibition region 251 is provided in the vicinity of the end side 182. The other configurations in FIG. 61 may be the same as those in FIG. 58. Also such a configuration can suppress wet-spreading of the solder.

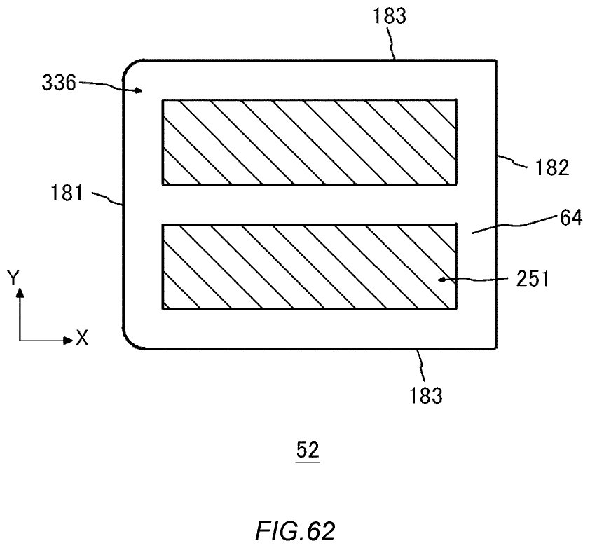

FIG. 62 is a diagram illustrating another example of the arrangement of the inhibition region 251. FIG. 62 is different from FIG. 58 in that the inhibition region 251 is not provided in the vicinity of the end side 183. That is, the unprocessed portion 336 may be provided in the vicinity of the end side 183. The other configurations in FIG. 62 may be the same as those in FIG. 58. Also such a configuration can suppress wet-spreading of the solder.

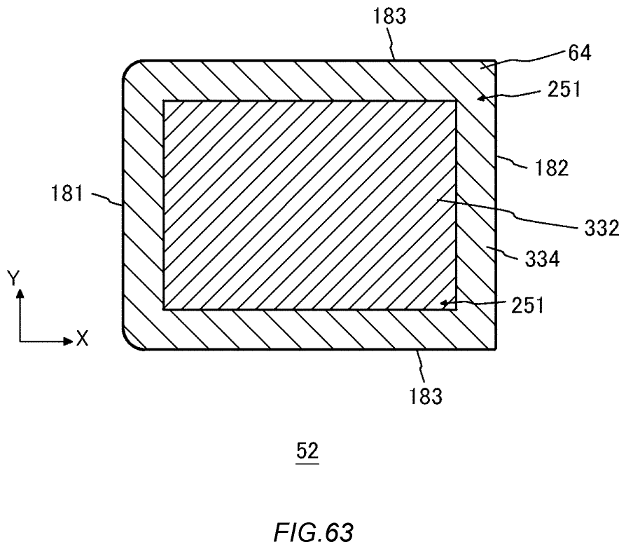

FIG. 63 is a diagram illustrating another example of the arrangement of the inhibition region 251. FIG. 63 illustrates an example of the arrangement of the inhibition regions 251 in the upper surface 64 of the chip connecting portion 52. In FIG. 63, the inhibition region 251 has an overlapping portion 332 and a non-overlapping portion 334, which are indicated by different hatching.

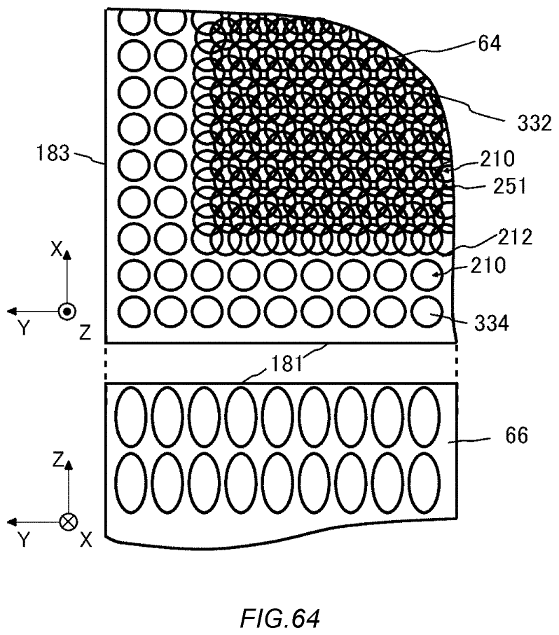

FIG. 64 is a diagram illustrating an example of the arrangement of the concave portions 210 of the upper surface 64 and the edge surface 66 in FIG. 63. FIG. 64 illustrates the arrangement of the plurality of concave portions 210 and the flat portion 212. The inhibition region 251 may be formed by forming the plurality of concave portions 210 and the flat portion 212. The inhibition region 251 may function as the rough surface region 51. The overlapping portion 332 can be formed by controlling a laser irradiation spot (irradiation position of laser irradiation). Note that the arrangement of the concave portions 210 in the overlapping portion 332 may be an irradiation position of laser irradiation. Note that the overlapping portion 332 may not have the flat portion 212 disposed between the two concave portions 210. That is, it may function as the rough surface region 51 without functioning as the inhibition region 251.

In the overlapping portion 332, the adjacent concave portions 210 overlap each other. In FIG. 64, the concave portion 210 is further provided between the adjacent concave portions 210. The overlapping portion 332 may be formed by further irradiating the flat portion 212 disposed between the adjacent concave portions 210 with a laser beam. The overlapping portion 332 may be a portion where the adjacent concave portions 210 are continuous. The flat portion 212 may or may not be provided in the overlapping portion 332. In the non-overlapping portion 334, the flat portion 212 is provided between the adjacent concave portions 210. The overlapping portion 332 can have a developed interfacial area ratio larger than that of the non-overlapping portion 334. On the other hand, the solder is easily wetted and spread in the overlapping portion 332 as compared with the non-overlapping portion 334.

In the present example, the overlapping portion 332 is provided inside the surface (upper surface 64) as compared with the non-overlapping portion 334. That is, the overlapping portion 332 is not provided in the vicinity of the end side 181, the end side 182, and the end side 183 of the upper surface 64. Providing the overlapping portion 332 inside the non-overlapping portion 334 suppresses wet-spreading of the solder from the edge surface 66 and the side surface 68 while increasing the developed interfacial area ratio.

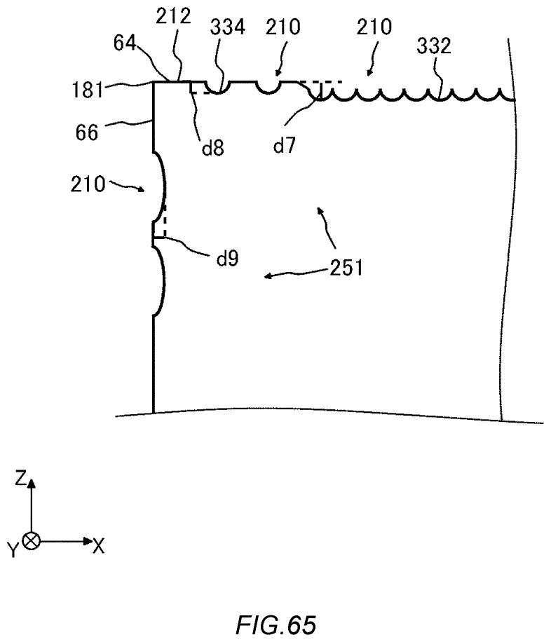

FIG. 65 is a diagram for explaining the shape of the overlapping portion 332. In the present example, the concave portion 210 is formed in the upper surface 64 and the edge surface 66 of the chip connecting portion 52 by laser irradiation. The concave portion 210 in the present example is a laser hole. The overlapping portion 332 is formed in the upper surface 64 of the chip connecting portion 52 by overlapping the irradiation positions of the laser irradiation.

A depth d7 of the concave portion 210 provided in the overlapping portion 332 is deeper than a depth d8 of the concave portion 210 provided in the non-overlapping portion 334. The depth d7 may be 1.5 times or more of the depth d8. The depth d7 of the concave portion 210 provided in the overlapping portion 332 is deeper than a depth d9 of the concave portion 210 formed in the edge surface 66. The depth d7 may be 1.5 times or more of the depth d9. Since the concave portion 210 provided in the overlapping portion 332 is deeper than the concave portion 210 provided in a portion other than the overlapping portion 332, the overlapping portion 332 and the non-overlapping portion 334 can be distinguished.

In FIG. 54 to FIG. 65, the inhibition region 251 of the chip connecting portion 52 has been described as an example, but the above-described configuration may be applied to the circuit pattern connecting portion 56 and other surfaces.

Description of Inhibition Portion 230

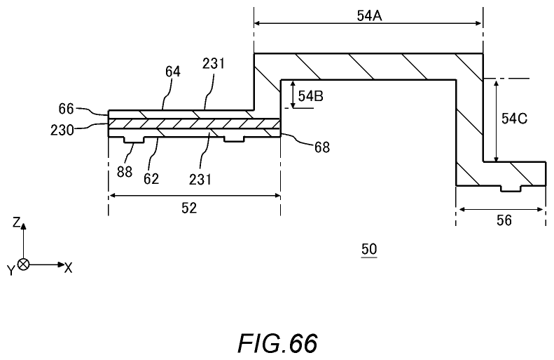

FIG. 66 is a diagram illustrating another example of the lead frame 50. The lead frame 50 of the present example is different from the examples of FIG. 1 to FIG. 34 in that the chip connecting portion 52 includes a main material portion 231 and an inhibition portion 230. The other structures may be the same as any of the forms described in FIG. 1 to FIG. 34.

The main material portion 231 is a portion formed of the same material as the lower surface 62. When the plurality of types of material portions is exposed at the lower surface 62, the main material portion 231 is formed of the same material as the portion having the largest area in the lower surface 62. The main material portion 231 is a portion formed of, for example, copper or an alloy containing copper. The main material portion 231 may be a portion formed of the same material as the bridge portion 54.

The inhibition portion 230 is a portion formed of a material having solder wettability lower than the main material portion 231. That is, the inhibition portion 230 is a portion where the solder is less likely to spread than the main material portion 231. The inhibition portion 230 is a portion formed of, for example, ceramic, carbon, aluminum, an alloy containing aluminum, iron, or an alloy containing iron.

The inhibition portion 230 is exposed at the edge surface 66 of the chip connecting portion 52. This can consequently suppress the solder from crawling up in the edge surface 66. The inhibition portion 230 may be exposed at the side surface 68 of the chip connecting portion 52. The chip connecting portion 52 may be formed of a clad material in which the main material portion 231 and the inhibition portion 230 are stacked. In the chip connecting portion 52, the inhibition portion 230 may be provided between the two main material portions 231.

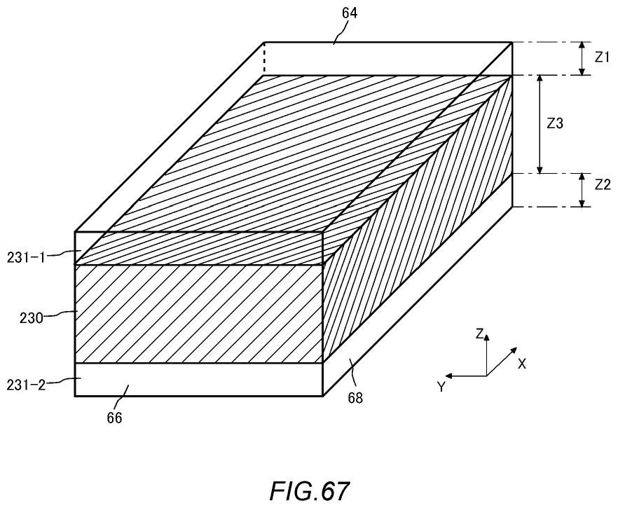

FIG. 67 is a diagram illustrating an arrangement example of the main material portion 231 and the inhibition portion 230 in the chip connecting portion 52. In FIG. 67, the inhibition portion 230 is hatched with oblique lines. The inhibition portion 230 covered by the main material portion 231 is also illustrated in a transparent manner through the main material portion 231.

In the chip connecting portion 52 in the present example, the plate-shaped main material portion 231 and the plate-shaped inhibition portion 230 are stacked in the height direction. The plate shape refers to a shape in which the area of the main surface substantially parallel to the upper surface 64 is larger than the area of any side surface substantially perpendicular to the upper surface 64. The chip connecting portion 52 illustrated in FIG. 67 includes a main material portion 231-1 exposed at the upper surface 64, a main material portion 231-2 exposed at the lower surface 62, and the inhibition portion 230 sandwiched between the two main material portions 231. The inhibition portion 230 is exposed at the edge surface 66 and each side surface 68. The inhibition portion 230 is exposed so as to cross each surface at a predetermined height position in each surface. That is, in the lateral direction, the width of the inhibition portion 230 is the same as the width of each surface. Such a shape can suppress the solder from crawling up in the edge surface 66 and each side surface 68.

The widths of the main material portion 231-1, the main material portion 231-2, and the inhibition portion 230 in the height direction are referred to as Z1, Z2, and Z3, respectively. The inhibition portion 230 may have the same width Z3 in the edge surface 66 and each side surface 68. The main material portion 231-1 may also have the same width Z1 in the edge surface 66 and each side surface 68. The main material portion 231-2 may also have the same width Z2 in the edge surface 66 and each side surface 68.

The width Z3 of the inhibition portion 230 is larger than both the width Z1 of the main material portion 231-1 and the width Z2 of the main material portion 231-2. The width Z3 may be larger than the sum of the width Z1 and the width Z2. This allows consequently easy suppression of the solder from crawling up in each surface. The width Z1 may be the same as, larger than, or smaller than the width Z2.

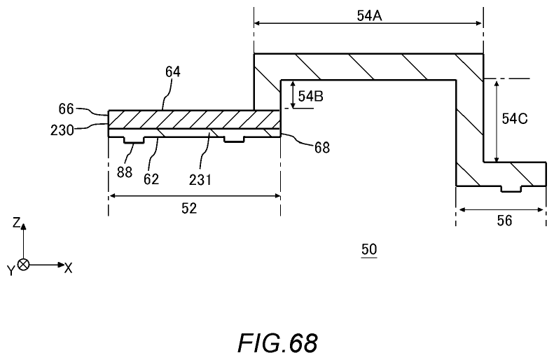

FIG. 68 is a diagram illustrating another example of the lead frame 50. The present example is different from the examples of FIG. 66 and FIG. 67 in that the inhibition portion 230 is exposed at the upper surface 64. The other structures are similar to the examples of FIG. 66 and FIG. 67.

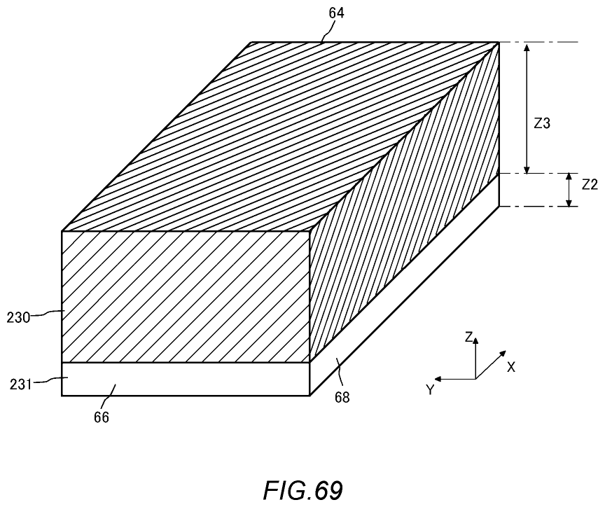

FIG. 69 is an enlarged schematic view of the chip connecting portion 52 of FIG. 68. As described above, the inhibition portion 230 of the present example is exposed at the upper surface 64. The inhibition portion 230 may be exposed at the entire upper surface 64. The chip connecting portion 52 of the present example does not have the main material portion 231-1 illustrated in FIG. 67.

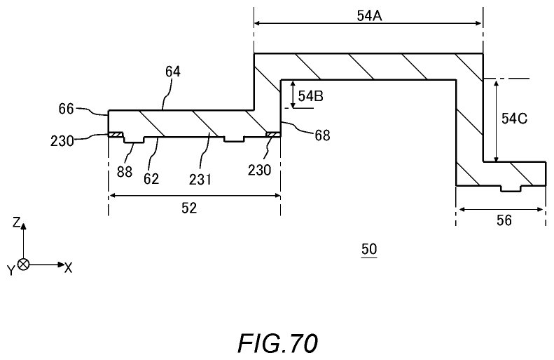

FIG. 70 is a diagram illustrating another example of the lead frame 50. In the present example, the shape of the inhibition portion 230 is different from those in the examples of FIG. 66 to FIG. 69. The other structures are similar to any of the examples in FIG. 66 to FIG. 69. The inhibition portion 230 of the present example is exposed at the lower surface 62.

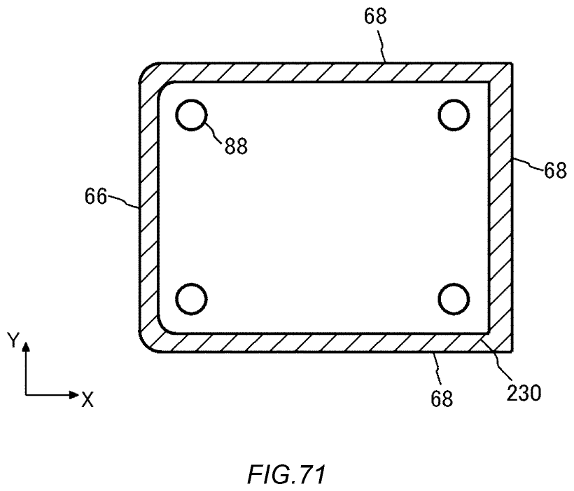

FIG. 71 is a diagram illustrating an arrangement example of the inhibition portions 230 in the lower surface 62 of the chip connecting portion 52. The inhibition portion 230 of the present example is disposed outside the protrusion 88 in the lower surface 62. The outside of the protrusion 88 refers to a region between the protrusion 88 and the edge surface 66 or the side surface 68.

The inhibition portion 230 may be in contact with the edge surface 66. The inhibition portion 230 may be exposed at the edge surface 66. The inhibition portion 230 may be in contact with the side surface 68. The inhibition portion 230 may be exposed at the side surface 68. The inhibition portion 230 may be apart from the protrusion 88. According to the present example, it is possible to suppress the solder from crawling up in the edge surface 66 and the side surface 68 while wetting most of the lower surface 62 with solder.

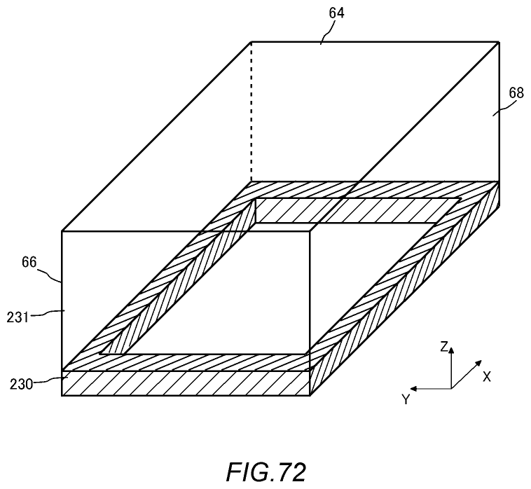

FIG. 72 is an enlarged schematic view of the chip connecting portion 52 in FIG. 70 and FIG. 71. As described above, the inhibition portion 230 of the present example is exposed at the lower surface 62. The inhibition portion 230 is exposed at the edge surface 66 and each side surface 68. As illustrated in FIG. 72, the inhibition portion 230 of the present example has a frame shape surrounding a predetermined region.

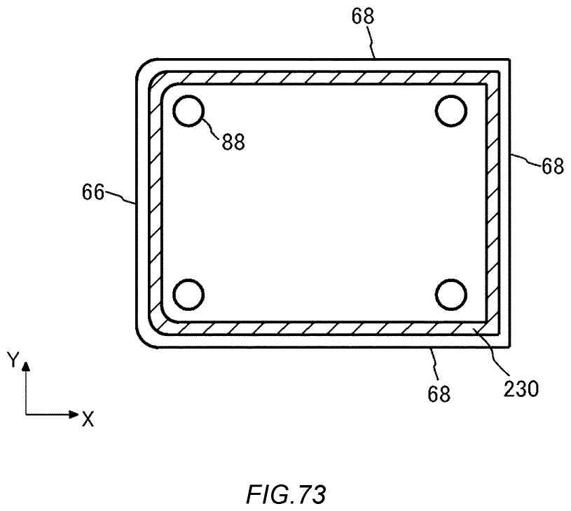

FIG. 73 is a diagram illustrating another arrangement example of the inhibition portion 230 in the lower surface 62 of the chip connecting portion 52. The inhibition portion 230 of the present example is disposed outside the protrusion 88 in the lower surface 62. However, the inhibition portion 230 is not in contact with the edge surface 66. That is, the inhibition portion 230 is not exposed at the edge surface 66. The inhibition portion 230 is not in contact with the side surface 68. That is, the inhibition portion 230 is not exposed at the side surface 68. The inhibition portion 230 may be apart from the protrusion 88. Also in the present example, it is possible to suppress the solder from crawling up in the edge surface 66 and the side surface 68 while wetting most of the lower surface 62 with solder.

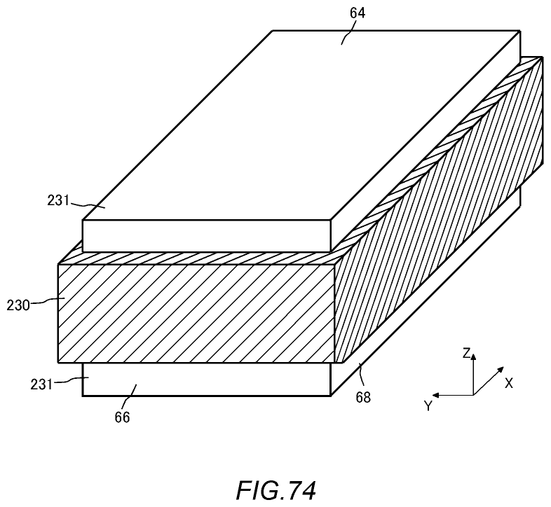

FIG. 74 is a diagram illustrating another arrangement example of the main material portion 231 and the inhibition portion 230 in the chip connecting portion 52. In FIG. 74, the inhibition portion 230 that is not covered by the main material portion 231 is illustrated. The inhibition portion 230 of the present example is different from the examples of FIG. 66 to FIG. 73 in that the inhibition portion protrudes outward from the main material portion 231 in a direction (X axis direction) perpendicular to the edge surface 66 of the chip connecting portion 52. The other structures are similar to any of the examples of FIG. 66 to FIG. 73. Also in each side surface 68, the inhibition portion 230 may protrude outward from the main material portion 231.

According to the present example, a step can be formed in the edge surface 66 and the side surface 68. Therefore, the crawling-up of the solder can be further suppressed. The inhibition portion 230 may have a plate shape as illustrated in FIG. 67 or FIG. 69. In this case, the area of the inhibition portion 230 in the XY plane is larger than the area of the main material portion 231. The inhibition portion 230 may have a frame shape as illustrated in FIG. 72. In this case, the main material portion 231 has a portion surrounded by the inhibition portion 230. The main material portion 231 may have a recess into which a part of the inhibition portion 230 is inserted, in any one of the edge surface 66 and the side surface 68.

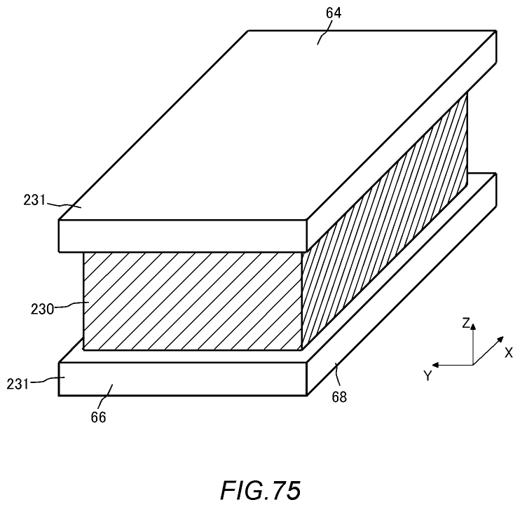

FIG. 75 is a diagram illustrating another arrangement example of the main material portion 231 and the inhibition portion 230 in the chip connecting portion 52. In FIG. 75, the inhibition portion 230 that is not covered by the main material portion 231 is illustrated. The inhibition portion 230 of the present example is different from the examples of FIG. 66 to FIG. 73 in that the inhibition portion is recessed inward from the main material portion 231 in the direction (X axis direction) perpendicular to the edge surface 66 of the chip connecting portion 52. The other structures are similar to any of the examples of FIG. 66 to FIG. 73. Also in each side surface 68, the inhibition portion 230 may be recessed inward from the main material portion 231.

According to the present example, a step can be formed in the edge surface 66 and the side surface 68. Therefore, the crawling-up of the solder can be further suppressed. The inhibition portion 230 may have a plate shape as illustrated in FIG. 67 or FIG. 69. In this case, the area of the inhibition portion 230 in the XY plane is smaller than the area of the main material portion 231. The inhibition portion 230 may have a frame shape as illustrated in FIG. 72. In this case, the main material portion 231 has a portion surrounded by the inhibition portion 230.

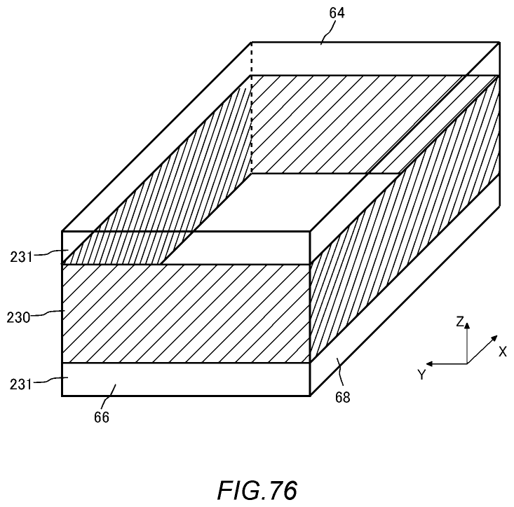

FIG. 76 is a diagram illustrating another arrangement example of the main material portion 231 and the inhibition portion 230 in the chip connecting portion 52. In FIG. 76, the inhibition portion 230 covered by the main material portion 231 is also illustrated in a transparent manner through the main material portion 231.

The inhibition portion 230 of the present example is stacked on the surface of the main material portion 231. For example, in the edge surface 66 of the chip connecting portion 52, the inhibition portion 230 is stacked with the main material portion 231 in a direction perpendicular to the edge surface 66. The inhibition portion 230 may also be stacked on each side surface 68.

In the present example, the inhibition portion 230 is formed by stacking a predetermined material on the surface of the main material portion 231 by a method such as sputtering or thermal spraying. The region where the inhibition portion 230 is exposed at each surface of the chip connecting portion 52 is similar to any of the examples described in FIG. 66 to FIG. 75. Also in the present example, it is possible to suppress the solder from crawling up in the edge surface 66 and the like.

The inhibition portion 230 may be formed of a ceramic such as aluminum oxide, aluminum nitride, or silicon nitride, may be formed of carbon, or may be formed of a metal such as iron. When the inhibition portion 230 is formed by sputtering or thermal spraying, the particle shape of the material with which the main material portion 231 is irradiated may be controlled. This can consequently control the roughness of the surface of the inhibition portion 230. The rough surface region 51 may be formed in the surface of the inhibition portion 230. The rough surface region 51 may be formed in the main material portion 231.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

In the present specification and the drawings, aspects described in the following items are also disclosed.

### (Item 1)

A semiconductor module comprising:

an insulating circuit board having a circuit pattern formed in one surface;

a semiconductor chip placed in the insulating circuit board;

a wiring portion for connecting the semiconductor chip and the circuit pattern; and

a resin package for protecting the semiconductor chip, wherein

the wiring portion includes:
a chip connecting portion connected to the semiconductor chip;
a circuit pattern connecting portion connected to the circuit pattern; and a bridge portion for connecting the chip connecting portion and the circuit pattern connecting portion,

the chip connecting portion has a lower surface facing the semiconductor chip,

the lower surface of the chip connecting portion has a first side farthest from the bridge portion, and

a step or an inclination along the first side is provided in the lower surface of the chip connecting portion over a length of half or more of the first side.

### (Item 2)

The semiconductor module according to item 1, wherein

the lower surface of the chip connecting portion has a second side closest to the bridge portion, and

the inclination or the step is provided along a side other than the second side among sides of the lower surface of the chip connecting portion,

### (Item 3)

The semiconductor module according to item 1 or 2, wherein the lower surface of the chip connecting portion is provided with a plurality of protrusions protruding toward the semiconductor chip, and

a height of the protrusions is lower than the step or the inclination,

### (Item 4)

The semiconductor module according to any one of items 1 to 3, wherein

the step is provided in the lower surface of the chip connecting portion, and

the step includes at least one of a protrusion protruding from the lower surface toward the circuit pattern and a groove recessed from the lower surface in a direction apart from the circuit pattern,

### (Item 5)

The semiconductor module according to item 4, wherein

the step is the protrusion and is provided in contact with the first side,

### (Item 6)

The semiconductor module according to item 4, wherein

the step is the groove and is provided in contact with the first side,

### (Item 7)

The semiconductor module according to item 4, wherein

the step is the groove and is provided apart from the first side,

### (Item 8)

The semiconductor module according to any one of items 1 to 3, wherein

the lower surface of the chip connecting portion is provided with the inclination, and

the inclination chamfers corner portions of the lower surface,

### (Item 9)

A semiconductor module comprising:

an insulating circuit board having a circuit pattern formed in one surface;

a semiconductor chip placed in the insulating circuit board; and

a wiring portion for electrically connecting the semiconductor chip and the circuit pattern, wherein

the wiring portion includes a chip connecting portion connected to the semiconductor chip, and

the chip connecting portion includes:

a main material portion; and

an inhibition portion formed of a material having solder wettability lower than the main material portion and disposed to be exposed at an edge surface.

### EXPLANATION OF REFERENCES

10: resin case
12: resin
13: coating layer
14: resin package
16: cooling portion
20: insulating board
22: heat dissipation plate
24: bonding layer
26: circuit pattern
30, 32, 34: bonding layer
39: region
40: semiconductor chip
50: lead frame (wiring portion)
51: rough surface region
52: chip connecting portion
54: bridge portion
56: circuit pattern connecting portion
62: lower surface
64: upper surface
65: corner
66: edge surface
68: side surface
70: step
71: retraction surface
74: opening
81: first side
82: second side
83: third side
84: through hole
86: terminal
88: protrusion
90: inclination
94: space
100: semiconductor module
152: chip connecting portion
160: insulating circuit board
181: end side
182: end side
183: end side
198: terminal connecting portion
201: vertex
202: space
203, 204: crack
210: concave portion
211: center
212: flat portion
214: recessed portion
216: raised portion
218: standard portion
230: inhibition portion
231: main material portion
251: inhibition region
310: light source
312: laser beam
314: bottom portion
320: die
322: first portion
324: second portion
332: overlapping portion
334: non-overlapping portion
336: unprocessed portion

What is claimed is:

1. A semiconductor module comprising:
an insulating circuit board having a circuit pattern formed in one surface;
a semiconductor chip placed in the insulating circuit board; and
a wiring portion for electrically connecting the semiconductor chip and the circuit pattern, wherein
the wiring portion includes a chip connecting portion connected to the semiconductor chip, and
a surface of the chip connecting portion includes:
a plurality of concave portions; and
a flat portion disposed between two concave portions.

2. The semiconductor module according to claim 1, wherein
a maximum width of each of the plurality of concave portions is 10 μm or more.

3. The semiconductor module according to claim 1, wherein
an interval of centers of at least two concave portions which are adjacent among the plurality of concave portions is 10 μm or more.

4. The semiconductor module according to claim 1, further comprising:
a bonding layer for bonding the semiconductor chip and the chip connecting portion, wherein
the bonding layer is provided in inner portions of at least some concave portions of the plurality of concave portions.

5. The semiconductor module according to claim 1, wherein
the surface in which the plurality of concave portions is formed includes a rough surface region having a developed interfacial area ratio of 0.2 or more.

6. The semiconductor module according to claim 1, wherein
the surface in which the plurality of concave portions is formed includes a rough surface region having a developed interfacial area ratio of 0.7 or less.

7. The semiconductor module according to claim 1, wherein
the plurality of concave portions is periodically disposed in at least two directions of at least any one surface of the chip connecting portion, and
any one surface of the chip connecting portion includes an unprocessed portion in which the periodic arrangement of the plurality of concave portions is interrupted.

8. The semiconductor module according to claim 1, wherein
the plurality of concave portions and the flat portion are formed at least in an edge surface of the chip connecting portion.

9. The semiconductor module according to claim 8, wherein
the plurality of concave portions is periodically disposed in at least two directions of the edge surface.

10. The semiconductor module according to claim 9, wherein
the plurality of concave portions is disposed with a predetermined gap in a lateral direction parallel to a lower surface of the chip connecting portion, and
the plurality of concave portions includes concave portions disposed side by side with the gap in a height direction perpendicular to the lateral direction.

11. The semiconductor module according to claim 10, wherein
widths of at least some concave portions of the plurality of concave portions in the lateral direction are larger than a width of the gap.

12. The semiconductor module according to claim 9, wherein
at least some concave portions of the plurality of concave portions have a width in a lateral direction parallel to a lower surface of the chip connecting portion larger than a width in a height direction perpendicular to the lateral direction.

13. The semiconductor module according to claim 9, wherein
a density of concave portions in a lateral direction parallel to a lower surface of the chip connecting portion of the plurality of concave portions is higher than a density of concave portions in a height direction perpendicular to the lateral direction.

14. The semiconductor module according to claim 9, wherein
a density of concave portions in a height direction perpendicular to a lower surface of the chip connecting portion of the plurality of concave portions is higher with increasing distance from the lower surface.

15. The semiconductor module according to claim 8, wherein
the chip connecting portion includes:
a main material portion; and
an inhibition portion formed of a material having solder wettability lower than the main material portion and disposed to be exposed at the edge surface.

16. The semiconductor module according to claim 15, wherein
in the edge surface, a width of the inhibition portion in a height direction perpendicular to a lower surface of the chip connecting portion is larger than a width of the main material portion in the height direction.

17. The semiconductor module according to claim 15, wherein
the inhibition portion is stacked with the main material portion in a height direction perpendicular to a lower surface of the chip connecting portion.

18. The semiconductor module according to claim 15, wherein
the inhibition portion is stacked with the main material portion in a direction perpendicular to the edge surface of the chip connecting portion.

19. The semiconductor module according to claim 15, wherein
the inhibition portion protrudes or is recessed from the main material portion in a direction perpendicular to the edge surface of the chip connecting portion.

20. The semiconductor module according to claim 8, wherein
the plurality of concave portions and the flat portion are formed in the edge surface, a side surface, and an upper surface of the chip connecting portion.

21. The semiconductor module according to claim 1, wherein
the wiring portion is a lead frame having a plate-shaped portion,
the flat portion includes:
a standard portion; and
a raised portion of which a height in a height direction perpendicular to a surface of the chip connecting portion is a same as that of the standard portion or raised in the height direction from the standard portion,
at least some concave portions of the plurality of concave portions are disposed to be recessed from the standard portion in the height direction, and
the raised portion is provided adjacent to the at least some concave portions.

22. The semiconductor module according to claim 21, wherein
the surface in which the plurality of concave portions is formed includes a rough surface region having a developed interfacial area ratio of 0.1 or more.

23. The semiconductor module according to claim 21, wherein
a depth of each of the plurality of concave portions is 20 μm or more and 200 μm or less.

24. The semiconductor module according to claim 22, wherein
the plurality of concave portions and the flat portion are formed in an upper surface of the chip connecting portion.

25. The semiconductor module according to claim 24, wherein
the plurality of concave portions and the flat portion are formed in an edge surface of the chip connecting portion, and
a depth of at least one concave portion formed in the upper surface among the plurality of concave portions is deeper than a depth of at least one concave portion formed in the edge surface.

26. The semiconductor module according to claim 21, wherein
the plurality of concave portions includes a die hole.

27. The semiconductor module according to claim 26, wherein
the plurality of concave portions includes a laser hole.

28. The semiconductor module according to claim 21, wherein
the plurality of concave portions and the flat portion are formed in an upper surface of the chip connecting portion, and
a shape of each of the plurality of concave portions in the upper surface is a polygonal shape.

29. The semiconductor module according to claim 28, wherein
the plurality of concave portions and the flat portion are formed in an edge surface of the chip connecting portion, and
a shape of each of the plurality of concave portions in the edge surface has a curved line.

30. The semiconductor module according to claim 21, wherein
at least some concave portions of the plurality of concave portions are compressed more than the flat portion.

31. The semiconductor module according to claim 21, wherein
the plurality of concave portions and the flat portion are formed in an upper surface and an edge surface of the chip connecting portion, and
a bottom portion of at least one concave portion formed in the upper surface among the plurality of concave portions is disposed on an opposite side to the edge surface of the chip connecting portion with respect to a center of the concave portion.

32. The semiconductor module according to claim 31, wherein
a depth of a concave portion formed in the upper surface among the plurality of concave portions becomes shallower with increasing distance from the edge surface.

33. The semiconductor module according to claim 24, wherein
a shortest distance between the plurality of concave portions and at least one end side of the surface is larger than an interval of concave portions which are adjacent among the plurality of concave portions.

34. The semiconductor module according to claim 33, wherein
the plurality of concave portions and the flat portion are formed in an edge surface of the chip connecting portion,
the upper surface of the chip connecting portion and the edge surface of the chip connecting portion are connected at an end side, and
a shortest distance between a concave portion formed in the upper surface of the chip connecting portion among the plurality of concave portions and the end side is larger than a shortest distance between a concave portion formed in the edge surface of the chip connecting portion and the end side.

35. The semiconductor module according to claim 33, wherein
the plurality of concave portions and the flat portion are formed in a side surface of the chip connecting portion,
the upper surface of the chip connecting portion and the side surface of the chip connecting portion are connected at an end side, and
a shortest distance between a concave portion formed in the upper surface of the chip connecting portion among the plurality of concave portions and the end side is larger than a shortest distance between a concave portion formed in the side surface of the chip connecting portion and the end side.

36. The semiconductor module according to claim 1, wherein
the surface is provided with:
an overlapping portion where adjacent concave portions among the plurality of concave portions overlap each other; and
a non-overlapping portion where the flat portion is provided between adjacent concave portions among the plurality of concave portions, and
the overlapping portion is provided inside the surface as compared with the non-overlapping portion.

37. The semiconductor module according to claim 1, wherein
the plurality of concave portions and the flat portion are formed in an upper surface of the chip connecting portion,
the upper surface has a first end side and a second end side opposite to the first end side, and
a maximum distance in intervals of concave portions sandwiched between the first end side and the second end side among the plurality of concave portions is larger than a first shortest distance between a concave portion formed in the upper surface of the chip connecting portion and the first end side and a second shortest distance between a concave portion formed in the upper surface of the chip connecting portion and the second end side.

38. The semiconductor module according to claim 37, wherein
an interval of concave portions at a center between the first end side and the second end side of the upper surface of the chip connecting portion among the plurality of concave portions is larger than the first shortest distance and the second shortest distance.

39. The semiconductor module according to claim 37, wherein
an interval of concave portions at a center between the first end side and the second end side of the upper surface of the chip connecting portion among the plurality of concave portions is the maximum distance.

40. The semiconductor module according to claim 37, wherein
the upper surface further has a third end side in contact with the first end side and the second end side, and
a shortest distance between a concave portion formed in the upper surface of the chip connecting portion among the plurality of concave portions and the third end side is larger than the first shortest distance and the second shortest distance.

41. The semiconductor module according to claim 40, wherein
the plurality of concave portions and the flat portion are formed in an edge surface of the chip connecting portion,
the upper surface of the chip connecting portion and the edge surface of the chip connecting portion are connected at the third end side, and
a shortest distance between a concave portion formed in the upper surface of the chip connecting portion among the plurality of concave portions and the third end side is larger than a shortest distance between a concave portion formed in the edge surface of the chip connecting portion and the third end side.

42. A semiconductor module comprising:
an insulating circuit board having a circuit pattern formed in one surface;
a semiconductor chip placed in the insulating circuit board;
a wiring portion having a rough surface region having a developed interfacial area ratio of 0.2 or more in at least a part of a surface and configured to connect the semiconductor chip and the circuit pattern; and
a resin package for protecting the semiconductor chip.

43. The semiconductor module according to claim 42, wherein
the developed interfacial area ratio of the rough surface region is larger than the developed interfacial area ratio of the circuit pattern.

44. The semiconductor module according to claim 43, wherein
the developed interfacial area ratio of the circuit pattern is 0.08 or less.

45. The semiconductor module according to claim 42, wherein
an arithmetic average height of the rough surface region is 10 μm or less.

46. The semiconductor module according to claim 42, wherein
a maximum height of the rough surface region is 100 μm or less.

47. The semiconductor module according to claim 42, wherein
the wiring portion is a lead frame having a plate-shaped portion, and includes:
a chip connecting portion connected to the semiconductor chip;
a circuit pattern connecting portion connected to the circuit pattern; and
a bridge portion for connecting the chip connecting portion and the circuit pattern connecting portion, and
the rough surface region is provided in the chip connecting portion.

48. The semiconductor module according to claim 47, wherein
an area of the chip connecting portion is larger than an area of the circuit pattern connecting portion.

49. The semiconductor module according to claim 47, wherein
the developed interfacial area ratio of the circuit pattern connecting portion is smaller than the developed interfacial area ratio of the rough surface region of the chip connecting portion.

50. The semiconductor module according to claim 47, wherein
the bridge portion has an opening.

51. The semiconductor module according to claim 47, wherein
a lower surface of the chip connecting portion or a lower surface of the circuit pattern connecting portion has a protrusion protruding toward the insulating circuit board.

52. The semiconductor module according to claim 47, further comprising:
a coating layer for covering at least a part of a surface of the lead frame and formed of a resin.

53. The semiconductor module according to claim 52, wherein
the chip connecting portion has an edge surface farthest from the bridge portion, and
the coating layer is provided in the edge surface.

54. The semiconductor module according to claim 52, wherein
a film thickness of the coating layer is 1 μm or more and 100 μm or less.

55. The semiconductor module according to claim 52, wherein
a surface of the coating layer has irregularities corresponding to irregularities of the rough surface region.

56. The semiconductor module according to claim 52, wherein
a surface of the coating layer is flatter than the rough surface region.

57. The semiconductor module according to claim 42, wherein
the resin package includes a resin case surrounding the insulating circuit board and a resin filled in the resin case.

58. The semiconductor module according to claim 47, wherein
the chip connecting portion has a lower surface facing the semiconductor chip,
the lower surface of the chip connecting portion has a first side farthest from the bridge portion, and
the lower surface of the chip connecting portion is provided with a step or an inclination along the first side over a length of half or more of the first side.

59. A method of manufacturing a semiconductor module including an insulating circuit board having a circuit pattern formed in one surface, a semiconductor chip placed in the insulating circuit board, and a wiring portion for electrically connecting the semiconductor chip and the circuit pattern, the wiring portion including a chip connecting portion connected to the semiconductor chip, the method comprising:
irradiating a surface of the chip connecting portion with a laser beam to form a plurality of concave portions and a flat portion disposed between two concave portions.

60. The method of manufacturing a semiconductor module according to claim 59, wherein
at least two surfaces of the chip connecting portion are irradiated with a laser beam by a common light source without replacement of the wiring portion to form a plurality of concave portions and a flat portion disposed between two concave portions on each of the surfaces.

61. The method of manufacturing a semiconductor module according to claim 60, wherein
each of the surfaces of the chip connecting portion is obliquely irradiated with a laser beam.

62. The method of manufacturing a semiconductor module according to claim 60, wherein
each of the surfaces of the chip connecting portion is irradiated with a laser beam without changing a focal position.

63. The method of manufacturing a semiconductor module according to claim 60, wherein
each of the surfaces of the chip connecting portion is irradiated with a laser beam by changing an irradiation angle without changing an arrangement of a laser light source.

64. The method of manufacturing a semiconductor module according to claim 59, wherein
a shape is transferred to an upper surface of the chip connecting portion by a die to form a plurality of concave portions and a flat portion disposed between two concave portions, and
after the shape is transferred by the die, at least an edge surface of the chip connecting portion is irradiated with a laser beam to form a plurality of concave portions and a flat portion disposed between two concave portions.

65. The method of manufacturing a semiconductor module according to claim 64, wherein
the upper surface of the chip connecting portion is irradiated with a laser beam to form a plurality of concave portions and a flat portion disposed between two concave portions.

66. The method of manufacturing a semiconductor module according to claim 65, wherein
laser irradiation is performed so as to overlap at least some of the plurality of concave portions which are formed by transferring a shape by the die.

67. A method of manufacturing a semiconductor module including an insulating circuit board having a circuit pattern formed in one surface, a semiconductor chip placed in the insulating circuit board, and a wiring portion for electrically connecting the semiconductor chip and the circuit pattern, the wiring portion including a chip connecting portion connected to the semiconductor chip, the method comprising:
transferring a shape to an upper surface of the chip connecting portion by a die to form a plurality of concave portions and a flat portion disposed between two concave portions.

68. The method of manufacturing a semiconductor module according to claim 67, wherein
the die has a quadrangular pyramid shape.
